(19) United States
(12) Patent Application Publication
(10) Pub. No.: US 2012/0267702 A1
(43) Pub. Date: Oct. 25, 2012

(54) VERTICAL MEMORY DEVICES AND METHODS OF MANUFACTURING THE SAME

(76) Inventors: Jung-Geun JEE, Seoul (KR); Jin-Gyun Kim, Yongin-si (KR); Jun-Kyu Yang, Seoul (KR); Ji-Hoon Choi, Seongnam-si (KR); Dong-Kyum Kim, Suwon-si (KR); Ki-Hyun Hwang, Seongnam-si (KR)

(21) Appl. No.: 13/442,482

(22) Filed: Apr. 9, 2012

(30) Foreign Application Priority Data
Apr. 20, 2011 (KR) 10-2011-0036603

(51) Int. Cl. H01L 29/792; H01L 21/336

(52) U.S. Cl. 257/324; 438/591; 257/E29.309; 257/E21.423

(57) ABSTRACT

A device includes a first GSL, a plurality of first word lines, a first SSL, a plurality of first insulation layer patterns, and a first channel. The first GSL, the first word lines, and the first SSL are spaced apart from each other on a substrate in a first direction perpendicular to a top surface of a substrate. The first insulation layer patterns are between the first GSL, the first word lines and the first SSL. The first channel on the top surface of the substrate extends in the first direction through the first GSL, the first word lines, the first SSL, and the first insulation layer patterns, and has a thickness thinner at a portion thereof adjacent to the first SSL than at portions thereof adjacent to the first insulation layer patterns.

### CROSS-REFERENCE TO RELATED APPLICATION

This application claims priority under 35 USC §119 to Korean Patent Application No. 10-2011-0036603 filed on Apr. 20, 2011, in the Korean Intellectual Property Office (KIPO), the entire contents of which is incorporated herein by reference.

### BACKGROUND

Example embodiments relate to vertical memory devices and methods of manufacturing the same. More particularly, example embodiments relate to non-volatile memory devices having a vertical channel and methods of manufacturing the same.

In order to increase an integration degree, vertical memory devices have been developed. In a method of manufacturing a vertical memory device, after alternately depositing a plurality of memory cells and insulation layers, the memory cells and the insulation layers are etched to form an opening. Polysilicon is deposited in the opening to form a channel. If the channel has a thick thickness, then the swing characteristics of the vertical memory device may deteriorate. If the channel has a thin thickness, the saturation current of the vertical memory device may decrease.

### SUMMARY

Example embodiments may provide vertical memory devices having good channel characteristics.

Example embodiments may provide methods of manufacturing vertical memory devices having good channel characteristics.

According to example embodiments, there is provided a vertical memory device. The device includes a first ground selection line (GSL), a plurality of first word lines, a first string selection line (SSL), a plurality of first insulation layer patterns, and a first channel. The first GSL, the first word lines and the first SSL are spaced apart from each other on a substrate in a first direction substantially perpendicular to a top surface of a substrate. The first insulation layer patterns are between the first GSL, the first word lines and the first SSL. The first channel on the top surface of the substrate extends in the first direction through the first GSL, the first word lines, the first SSL and the first insulation layer patterns, and has a thickness thinner at a portion thereof adjacent to the first SSL than at portions thereof adjacent to the first insulation layer patterns.

In example embodiments, the channel may have a recess at an outer lateral portion thereof, and the first SSL is adjacent to the recess.

In example embodiments, portions of the channel adjacent to the first word lines and the first GSL may have a thickness thinner than portions of the first channel adjacent to the first insulation layer patterns.

In example embodiments, the first channel includes an inner wall that is cup shaped.

In example embodiments, the vertical memory device may further include a filling layer pattern filling a space defined by the inner wall of the cup shaped channel.

In example embodiments, the first channel may have a pillar shape.

In example embodiments, the first channel may include polysilicon.

In example embodiments, the vertical memory device may further include a tunnel insulation layer pattern, a charge trapping layer pattern and a blocking layer pattern sequentially stacked in a direction substantially perpendicular to a sidewall of the first channel. The tunnel insulation layer pattern, the charge trapping layer pattern, and the blocking layer pattern are disposed between the sidewall of the first channel and each of the first GSL, the first word lines, and the first SSL.

In example embodiments, the tunnel insulation layer pattern, the charge trapping layer pattern, and the blocking layer pattern may be also sequentially stacked in the first direction between the first insulation layer patterns and each of the first GSL, the first word lines and the first SSL.

In example embodiments, the first channel is one of a plurality of channels formed in an array in a second direction and a third direction perpendicular to the second direction on the top surface of the substrate. Each of the first GSL, the first word lines, and the first SSL may have a bar shape extending in the second direction.

In example embodiments, additional channels, GSLs, word lines, and SSLs may be spaced apart from the first channel, the first GSL, the first word lines, and the first SSL, respectively, in a third direction substantially perpendicular to the second direction.

In example embodiments, the vertical memory device may further include a bit line electrically connected to a set of channels extending in the third direction.

According to other example embodiments, there is provided a vertical memory device. The device includes a plurality of conductive lines, a plurality of insulation layer patterns, and a channel. The conductive lines are spaced apart from each other on a substrate in a vertical direction substantially perpendicular to a top surface of a substrate. The insulation layer patterns are disposed between two consecutive conductive lines. The channel disposed on the top surface of the substrate and extending in the vertical direction through the conductive lines and the insulation layer patterns, and includes at least a first laterally recessed portion at a first vertical level and at least a first laterally non-recessed portion at a second vertical level.

According to example embodiments, there is provided a method of manufacturing a vertical memory device. In the method, a plurality of sacrificial layers and first insulation layers are formed alternately and repeatedly on a substrate in a first direction. A first opening is formed through the plurality of sacrificial layers and first insulation layers to expose a top surface of the substrate. A channel layer is formed in the first openings and on the substrate. A second opening is formed through the plurality of sacrificial layers and first insulation layers to expose the top surface of the substrate, the second opening is located adjacent to the first opening in a second direction perpendicular to the first direction. The sacrificial layers are removed to form a plurality of gaps between the plurality of first insulation layers to expose outer sidewalls of the channel layer by the plurality of gaps. The exposed outer sidewalls of the channel layer are partially removed to form recesses in the channel layer. A plurality of conductive layers are filled to fill the plurality of gaps.

### BRIEF DESCRIPTION OF THE DRAWINGS

Example embodiments will be more clearly understood from the following detailed description taken in conjunction with the accompanying drawings. FIGS. 1-37 represent non-limiting, example embodiments as described herein.

FIGS. 1A, 1B and 1C are a perspective diagram, a local perspective diagram and a cross-sectional view, respectively, illustrating vertical memory devices in accordance with example embodiments;

FIGS. 2A and 2B are a local perspective diagram and a cross-sectional view, respectively, illustrating vertical memory devices in accordance with other example embodiments;

FIGS. 3A and 3B are a local perspective diagram and a cross-sectional view, respectively, illustrating vertical memory devices in accordance with still other example embodiments;

FIGS. 4-18 are cross-sectional views illustrating methods of manufacturing a vertical memory device of FIGS. 1 to 3 in accordance with example embodiments;

FIGS. 19A and 19B are a perspective diagram and a local perspective diagram, respectively, illustrating vertical memory devices in accordance with still other example embodiments;

FIGS. 20A and 20B are a perspective diagram and a local perspective diagram, respectively, illustrating vertical memory devices in accordance with still other example embodiments;

FIGS. 21A and 21B are a perspective diagram and a local perspective diagram, respectively, illustrating vertical memory devices in accordance with still other example embodiments; and

FIGS. 22-37 are perspective diagrams illustrating methods of manufacturing a vertical memory device of FIGS. 19 to 21 in accordance with example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as limited to the example embodiments set forth herein. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

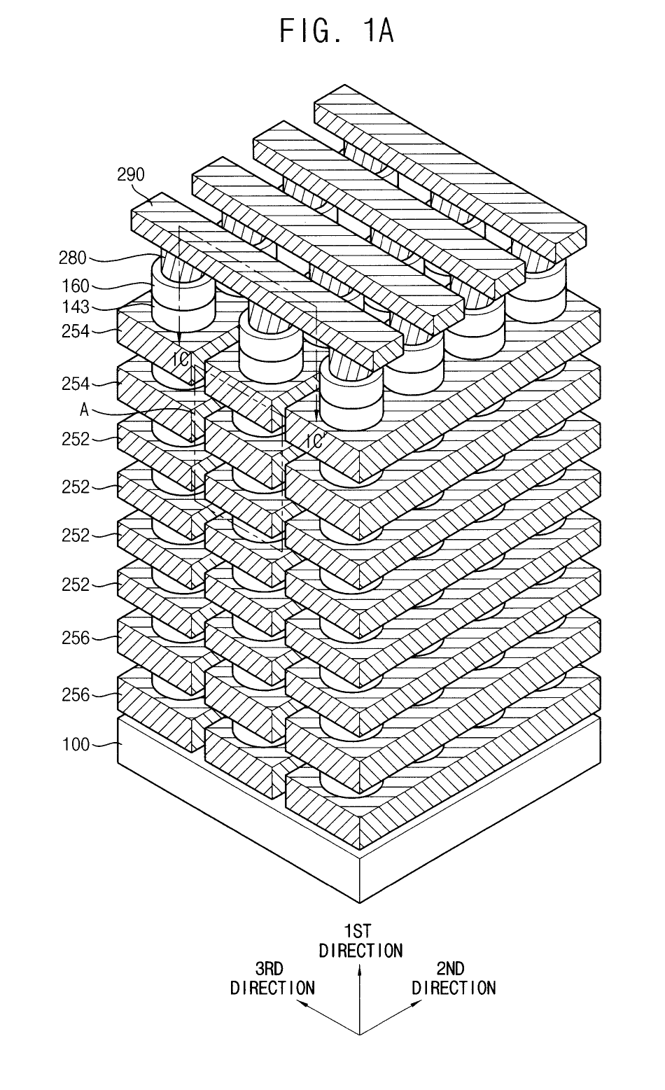

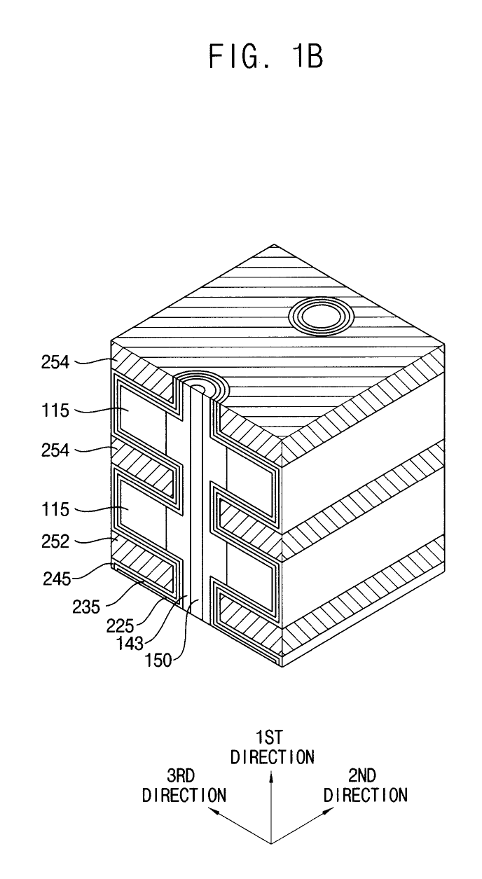

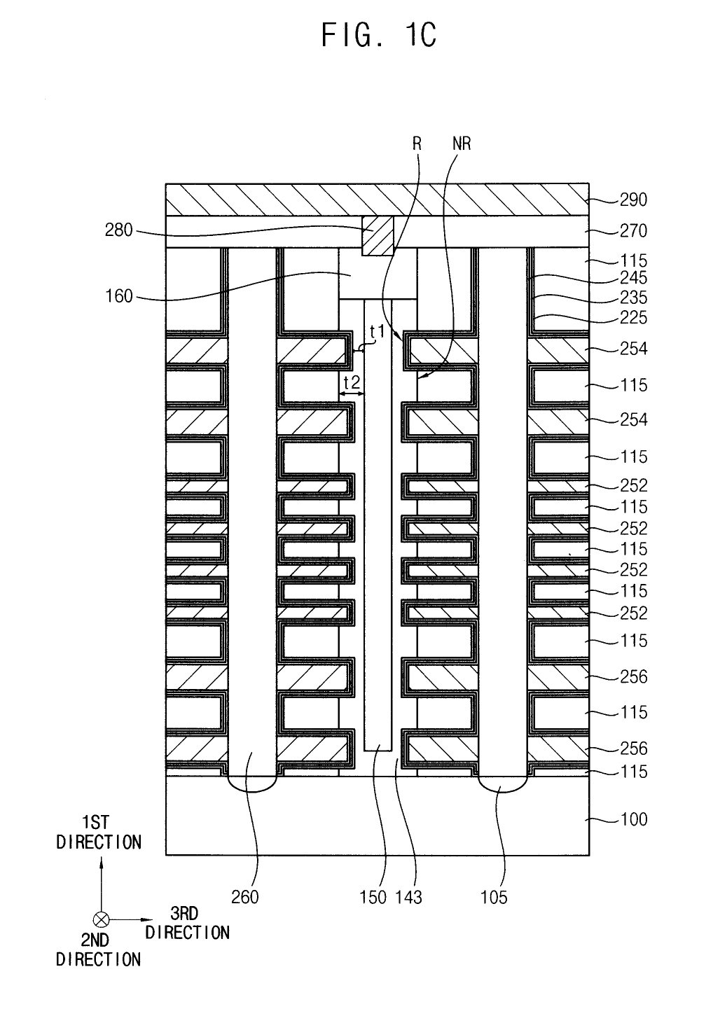

FIGS. 1A, 1B and 1C are a perspective diagram, a local perspective diagram and a cross-sectional view, respectively, illustrating vertical memory devices in accordance with example embodiments. FIG. 1B is a local perspective diagram of region A of a vertical memory device in FIG. 1A, and FIG. 1C is a cross-sectional view of a vertical memory device in FIG. 1A cut along the line IC-IC′.

Referring to FIGS. 1A, 1B and 1C, a vertical memory device may include a ground selection line (GSL) 256, a word line 252 and a string selection line (SSL) 254 that are spaced apart from each other along a first direction substantially perpendicular to a top surface of a substrate 100, and a first channel 143 extending from the substrate 100 in the first direction through the GSL 256, the word line 252 and the SSL 254. The vertical memory device may further include an impurity region 105 serving as a common source line (CSL) and a bit line 290.

Each of the GSL 256, the word line 252 and the SSL 254 may be at a single level (e.g., one of each, each at a different height) or more than one level, and a first insulation layer pattern 115 may be interposed therebetween. According to one example embodiment, the GSL 256 and the SSL 254 are at 2 levels (e.g., two of each at different heights), respectively, and the word line 252 is at 4 levels between the GSL 256 and the SSL 254. However, the GSL 256 and the SSL 254 may be at one level, and the word line 252 may be formed at 2, 8 or 16 levels. According to example embodiments, each of the GSL 256, the word line 252 and the SSL 254 may extend in the second direction, and a plurality of GSLs 256, a plurality of word lines 252, and a plurality of SSLs 254 may be disposed in the third direction perpendicular to the second direction.

According to example embodiments, the GSL 256, the word line 252 and the SSL 254 include, for example, a metal and/or a metal nitride. For example, the GSL 256, the word line 252 and the SSL 254 may include a metal and/or a metal nitride with low electrical resistance (e.g., tungsten, tungsten nitride, titanium, titanium nitride, tantalum, tantalum nitride and/or platinum). According to one example embodiment, each of the GSL 256, the word line 252 and the SSL 254 may be a multi-layered structure including a barrier layer, for example, a metal nitride and/or a metal layer including a metal. The first insulation layer pattern 115 may include, for example, a silicon oxide (e.g., silicon dioxide (SiO₂), silicon oxycarbide (SiOC) and/or silicon oxyfluoride (SiOF)).

The first channel 143 may include an inner wall that has a hollow cylindrical shape such as a cup shape, and may extend in the first direction through the GSL 256, the word line 252, the SSL 254 and the first insulation layer pattern 115 therebetween. A filling layer pattern 150 may be formed in a space defined by the inner wall of the, for example, cup shaped first channel 143. The filling layer pattern 150 may include, for example, an insulating material (e.g., an oxide).

A portion of the first channel 143 adjacent to the GSL 256, the word line 252 and the SSL 254 may have a thickness smaller than a portion of the first channel 143 adjacent to the first insulation layer pattern 115. The thickness of the first channel 143 may be referred as “width” or “diameter” at the same vertical level. According to example embodiments, the first channel 143 may have a plurality of recesses R at outer lateral portions adjacent to the GSL 256, the word line 252 and the SSL 254. In one embodiment, the first channel 143 may have a plurality of non-recesses NR at outer lateral portions adjacent to the first insulation layer pattern 115. A thickness t1 of the first channel 143 is shown between one side of one of the recesses R and an outer side of the filling layer pattern 150 at a first vertical level (e.g., a level of one of the GSL 256, the word line 252, and the SSL 254). A thickness t2 of the first channel 143 is referred between one side of one of the non-recesses NR and an outer side of the filling layer pattern 150 at the same vertical level (e.g., a level of one of the first insulation layer pattern 115). A shape of the first channel 143 may be ridge-shaped including alternating laterally recessed regions and non-recessed regions extending in the first direction.

The first channel 143 may include for example, polysilicon or doped polysilicon.

According to example embodiments, a plurality of first channels 143 may be formed in the second direction to define a first channel column, and a plurality of first channel columns may be formed in a third direction substantially perpendicular to the second direction to define a first channel array.

A pad 160 may be on the filling layer pattern 150 and the first channel 143. The pad 160 may electrically connect the first channel 143 to the bit line 290 via a bit line contact 280. The pad 160 may serve as a source/drain region by which charges may be moved through the first channel 143.

The pad 160 may include doped polysilicon.

A tunnel insulation layer pattern 225, a charge trapping layer pattern 235 and a blocking layer pattern 245 may be disposed between each of the GSL 256, the word line 252 and the SSL 254, and an outer sidewall of the first channel 143 in a direction substantially perpendicular to the outer sidewall of the first channel 143. The tunnel insulation layer pattern 225, the charge trapping layer pattern 235 and the blocking layer pattern 245 may be sequentially stacked between each of the GSL 256, the word line 252 and the SSL 254, and the first insulation layer pattern 115 and/or on a sidewall of the first insulation layer pattern 115. According to at least one example embodiment, the tunnel insulation layer pattern 225 may be only on the outer sidewall of the first channel 143.

According to example embodiments, the tunnel insulation layer pattern 225 may include a silicon oxide, and the charge trapping layer pattern 235 may include a nitride (e.g., a silicon nitride and/or a metal oxide). According to example embodiments, the blocking layer pattern 245 may include a silicon oxide and/or a metal oxide (e.g., aluminum oxide, hafnium oxide, lanthanum oxide, lanthanum aluminum oxide, lanthanum hafnium oxide, hafnium aluminum oxide, titanium oxide, tantalum oxide and/or zirconium oxide). According to at least one example embodiment, the blocking layer pattern 245 may be a multi-layered structure of a silicon oxide layer and a metal oxide layer.

A second insulation layer pattern 260 may be disposed between structures each of which may include the GSL 256, the word line 252 and the SSL 254 extending in the second direction and the first insulation layer pattern 115 therebetween. The second insulation layer pattern 260 may include an insulating material (e.g., an oxide). The impurity region 105 may be at an upper portion of the substrate 100 beneath the second insulation layer pattern 260, which may extend in the second direction and serve as the CSL. According to example embodiments, the impurity region 105 may include n-type impurities, for example, phosphorus and/or arsenic. A metal silicide pattern (not shown), e.g., a cobalt silicide pattern may be further formed on the impurity region 105.

The bit line 290 may be electrically connected to the pad 160 via the bit line contact 280, and may be electrically connected to the first channel 143. The bit line 290 may include, for example, a metal, a metal nitride and/or doped polysilicon. According to example embodiments, the bit line 290 may extend in the third direction, and a plurality of bit lines 290 may be formed in the second direction.

The bit line contact 280 may be contained in a third insulation layer 270, and contact the pad 160. The bit line contact 280 may include, for example, a metal, a metal nitride and/or doped polysilicon.

The third insulation layer 270 may be on the first and second insulation layer patterns 115 and 260, the pad 160, the blocking layer pattern 245, the charge trapping layer pattern 235 and the tunnel insulation layer pattern 225. According to example embodiments, the third insulation layer 270 may include an insulating material, for example, an oxide.

The vertical memory device may include the first channel 143 having a relatively thin thickness at a portion thereof adjacent to the GSL 256, the word line 252 and the SSL 254. Thus, transistors including the GSL 256, the word line 252 and the SSL 254, i.e., a GST (Ground Selection Transistor), a cell transistor, and an SST (String Selection Transistor) may have good swing characteristics because the current change according to the voltage change is high. Particularly, the first channel 143 may not have a thin thickness as a whole but a thin thickness only at a portion adjacent to the GSL 256, the word line 252 and the SSL 254. Thus, the GSL 256, the word line 252 and the SSL 254 may have a relatively large area when compared to those on a channel having a constant thickness. Accordingly, the GSL 256, the word line 252 and the SSL 254 may have a low resistance.

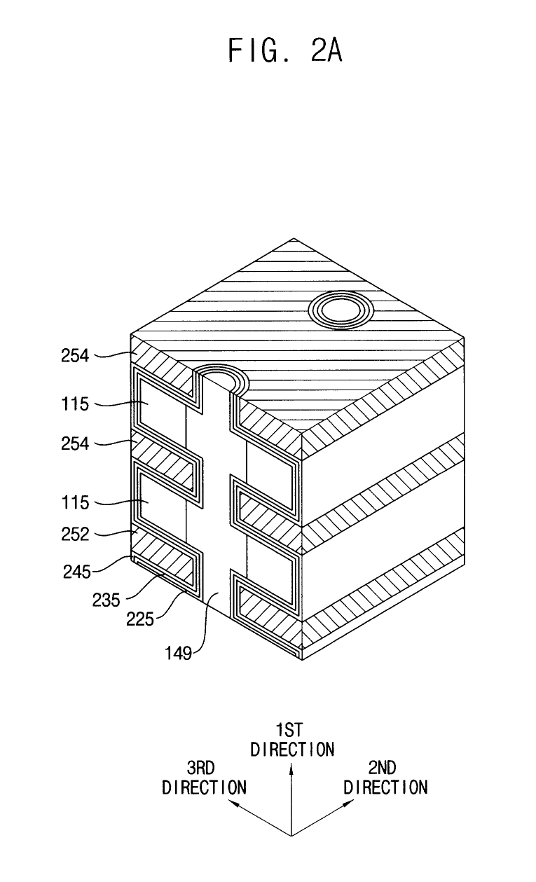

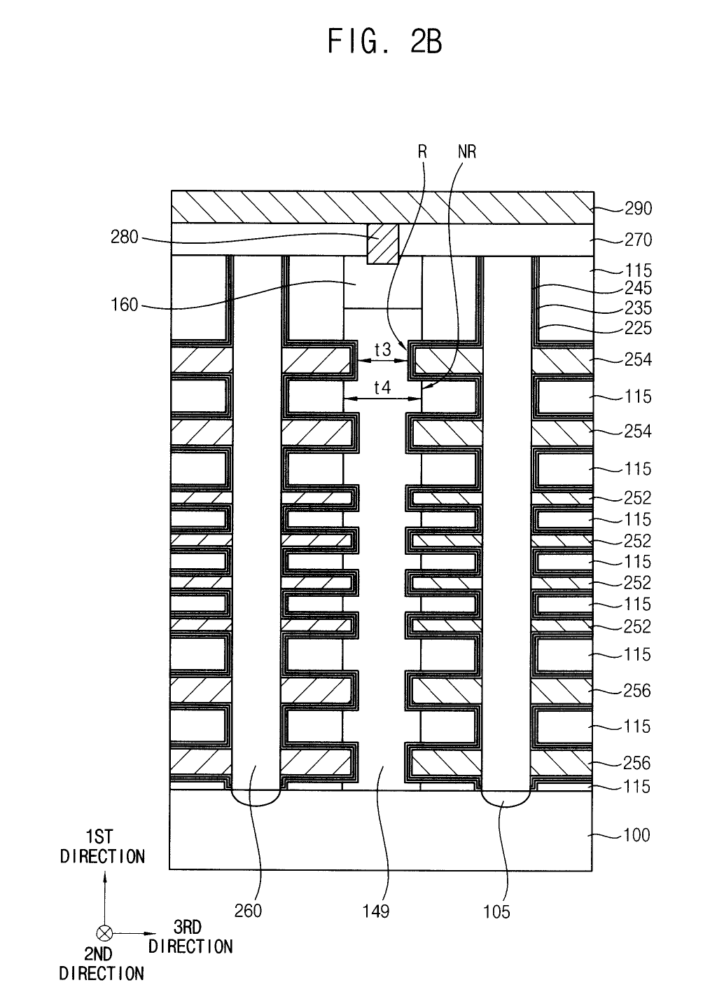

FIGS. 2A and 2B are a local perspective diagram and a cross-sectional view, respectively, illustrating vertical memory devices in accordance with other example embodiments. The vertical memory devices may be substantially the same as those illustrated with reference to FIGS. 1A, 1B and 1C except for a filling layer pattern and the shape of a channel, and thus brief explanations are provided herein.

In one embodiment, a second channel 149 may have a pillar shape and may be disposed through the GSL 256, the word line 252, the SSL 254 and the first insulation layer pattern 115 therebetween. For example, the vertical memory devices may not have a filling layer pattern in the second channel 149.

The second channel 149 may have a thickness that is thinner at a portion thereof adjacent to the GSL 256, the word line 252 and the SSL 254 than a thickness at a portion thereof adjacent to the first insulation layer pattern 115. According to example embodiments, the second channel 149 may have a plurality of recesses R at outer lateral portions adjacent to the GSL 256, the word line 252 and the SSL 254. In one embodiment, the second channel 149 may have a plurality of non-recesses NR at outer lateral portions adjacent to the first insulation pattern 115. A thickness t3 of the second channel 149 is shown between two recesses R of the second channel 149 at a first vertical level (e.g., a level of one of the GSL 256, the word line 252, and the SSL 254). A thickness t4 of the second channel 149 is shown between two non-recesses NR of the second channel 149 at a second vertical level (e.g., a level of one of the first insulation layer pattern 115).

According to example embodiments, a plurality of second channels 149 may be formed in the second direction to define a second channel column, and a plurality of second channel columns may be formed in a third direction substantially perpendicular to the second direction to define a second channel array.

The vertical memory device may include the second channel 149 having a relatively thin thickness at a portion thereof adjacent to the GSL 256, the word line 252 and the SSL 254. Thus, transistors including the GSL 256, the word line 252 and the SSL 254, i.e., a GST, a cell transistor, and an SST may have good swing characteristics. Particularly, the second channel 149 may not have a thin thickness as a whole but a thin thickness only at a portion adjacent to the GSL 256, the word line 252 and the SSL 254. Thus, the GSL 256, the word line 252 and the SSL 254 may have a relatively large area when compared to those on a channel having a constant thickness. Accordingly, the GSL 256, the word line 252 and the SSL 254 may have a low resistance.

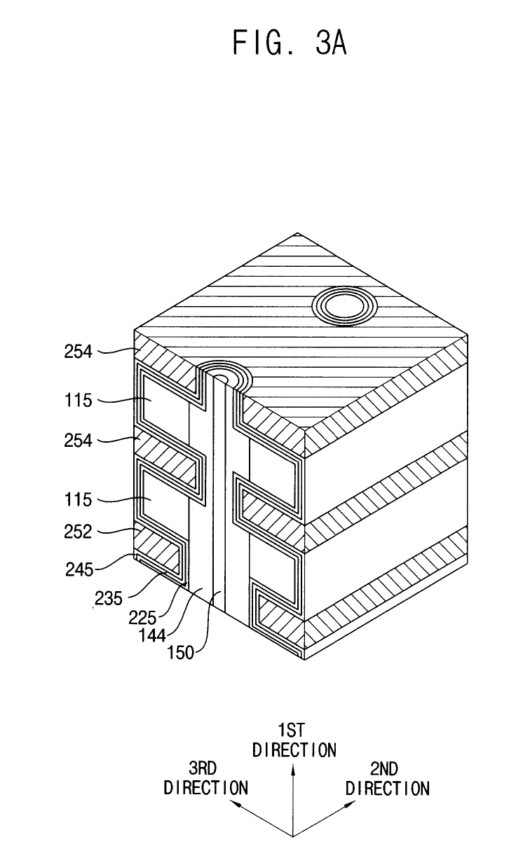

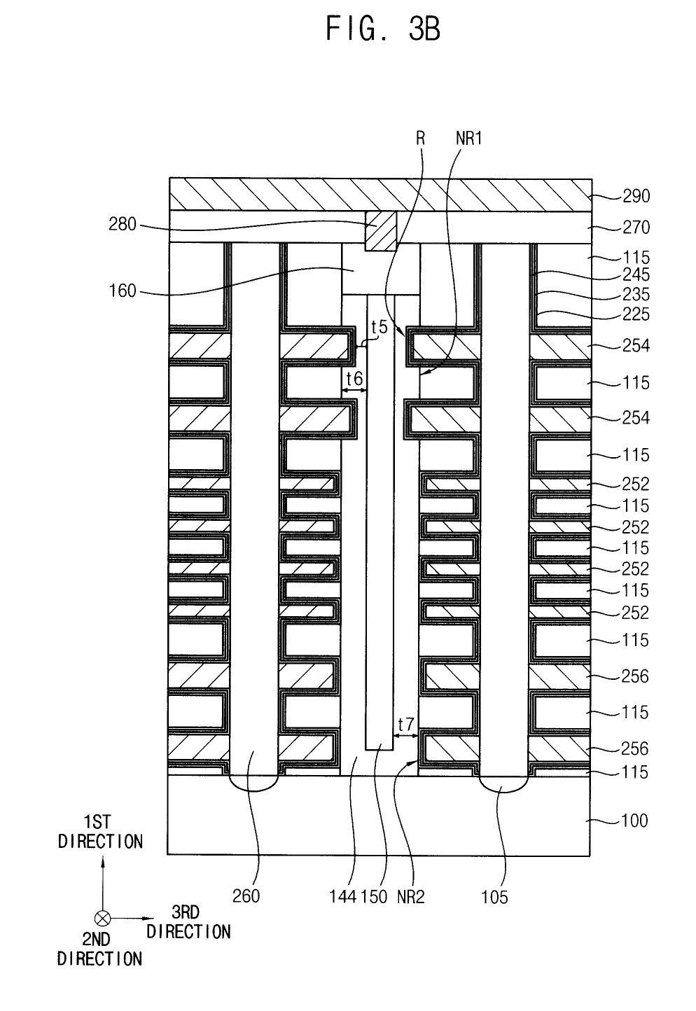

FIGS. 3A and 3B are a local perspective diagram and a cross-sectional view, respectively, illustrating vertical memory devices in accordance with still other example embodiments. The vertical memory devices may be substantially the same as those illustrated with reference to FIGS. 1A, 1B and 1C except for the shape of a channel, and thus brief explanations are provided herein.

In one embodiment, a third channel 144 may have a hollow cylindrical shape, such as a cup shape and may be disposed through the GSL 256, the word line 252, the SSL 254 and the first insulation layer pattern 115 therebetween. For example, the vertical memory devices may have a filling layer pattern 150 in a space defined by an inner sidewall of the, for example, cup shaped third channel 144.

The third channel 144 may have a thickness that is thinner at a portion thereof adjacent to the SSL 254 than a thickness at a portion thereof adjacent to the first insulation layer pattern 115. Unlike the first channel 143, a thickness of a portion of the third channel 144 adjacent to the GSL 256 and the word line 252 may be substantially the same as a thickness of a portion of the third channel 144 adjacent to the first insulation layer pattern 115, and thus only the thickness of the portion of the third channel 144 adjacent to the SSL 254 may be thinner than the thickness at a portion thereof adjacent to the first insulation layer pattern 115. According to example embodiments, the third channel 144 may have a recess R at an outer lateral portion adjacent to the SSL 254. In one embodiment, the third channel 144 may have a first plurality of non-recesses NR1 at outer lateral portions adjacent to the first insulation pattern 115 and a second plurality of non-recesses NR2 at outer lateral portions adjacent to the GSL 256 and the word line 252. A thickness t5 of the third channel 144 is shown between one side of one of the recesses R and an outer side of the filling layer pattern 150 at a first vertical level (e.g., a level of one of the SSL 254). A thickness t6 of the third channel 144 is shown between one side of one of the non-recesses NR1 and an outer side of the filling layer pattern 150 at the same vertical level (e.g., a level of one of the first insulation layer pattern 115). A thickness t7 of the third channel 144 is shown between one side of one of the non-recesses NR2 and an outer side of the filling layer pattern 150 at the same vertical level (e.g., a level of one of the GSL 256 and the word line 252).

According to example embodiments, a plurality of third channels 144 may be formed in the second direction to define a third channel column, and a plurality of third channel columns may be formed in the third direction to define a third channel array.

The vertical memory device may include the third channel 144 having a relatively thin thickness at a portion thereof adjacent to the SSL 254. Thus, a transistor including the SSL 254, i.e., an SST may have good swing characteristics. Particularly, the third channel 144 may not have a thin thickness as a whole but a thin thickness only at a portion adjacent to the SSL 254.

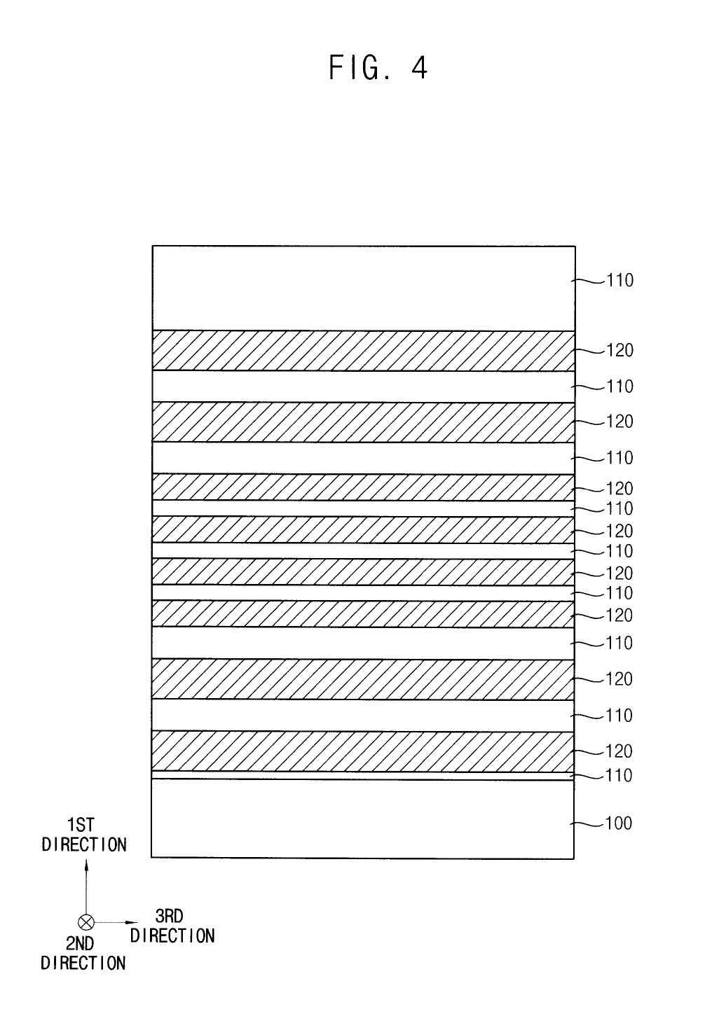

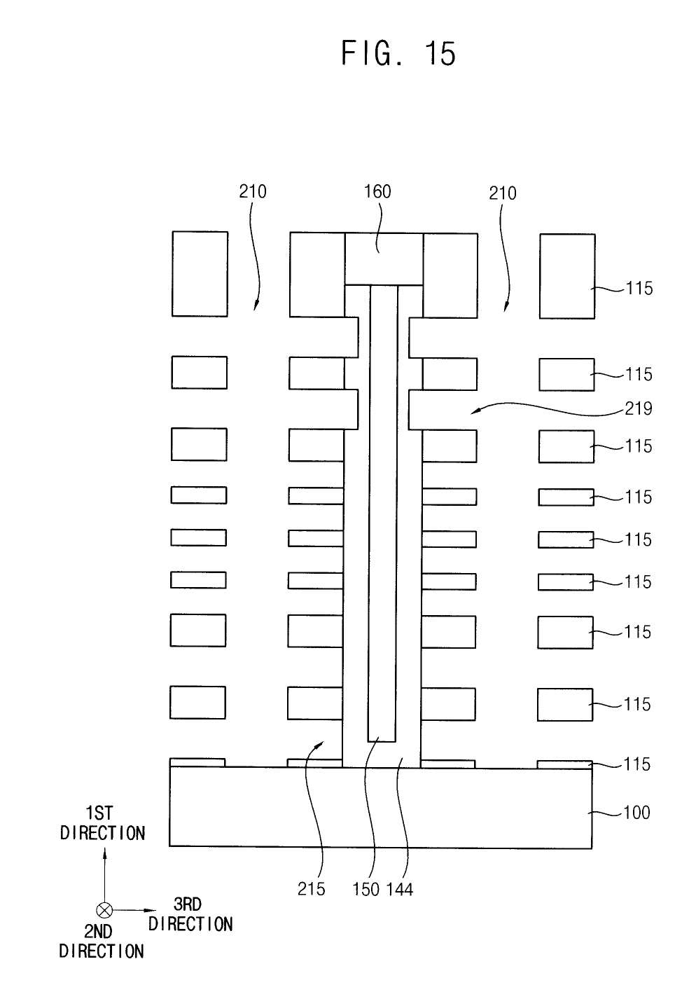

FIGS. 4-18 are cross-sectional diagrams illustrating methods of manufacturing a vertical memory device of FIGS. 1 to 3 in accordance with example embodiments. Particularly, FIGS. 4-8, 11-14 and 16-18 are cross-sectional diagrams illustrating methods of manufacturing the vertical memory device of FIGS. 1A, 1B and 1C, FIGS. 9-10 are cross-sectional diagrams illustrating methods of manufacturing the vertical memory device of FIGS. 2A and 2B, and FIG. 15 is a cross-sectional diagram illustrating methods of manufacturing the vertical memory device of FIGS. 3A and 3B.

Referring to FIG. 4, a first insulation layer 110 and a sacrificial layer 120 may be alternately and repeatedly formed on a substrate 100. A plurality of first insulation layers 110 and a plurality of sacrificial layers 120 may be alternately formed on each other at a plurality of levels, respectively. The substrate 100 may include a semiconductor material, for example, silicon and/or germanium. The substrate 100 may be, for example, a bulk semiconductor or a semiconductor layer.

According to example embodiments, the first insulation layer 110 and the sacrificial layer 120 may be formed by, for example, a chemical vapor deposition (CVD) process, a plasma enhanced chemical vapor deposition (PECVD) process and/or an atomic layer deposition process (ALD) process. The first insulation layer 110, which may be formed directly on a top surface of the substrate 100, may be formed by, for example, a thermal oxidation process. According to example embodiments, the first insulation layer 110 may be formed to include a silicon oxide, for example, silicon dioxide (SiO₂), silicon oxycarbide (SiOC) and/or silicon oxyfluoride (SiOF). The sacrificial layer 120 may be formed to include, for example, a material with etch selectivity to the first insulation layer 110 (e.g., silicon nitride and/or silicon boronitirde).

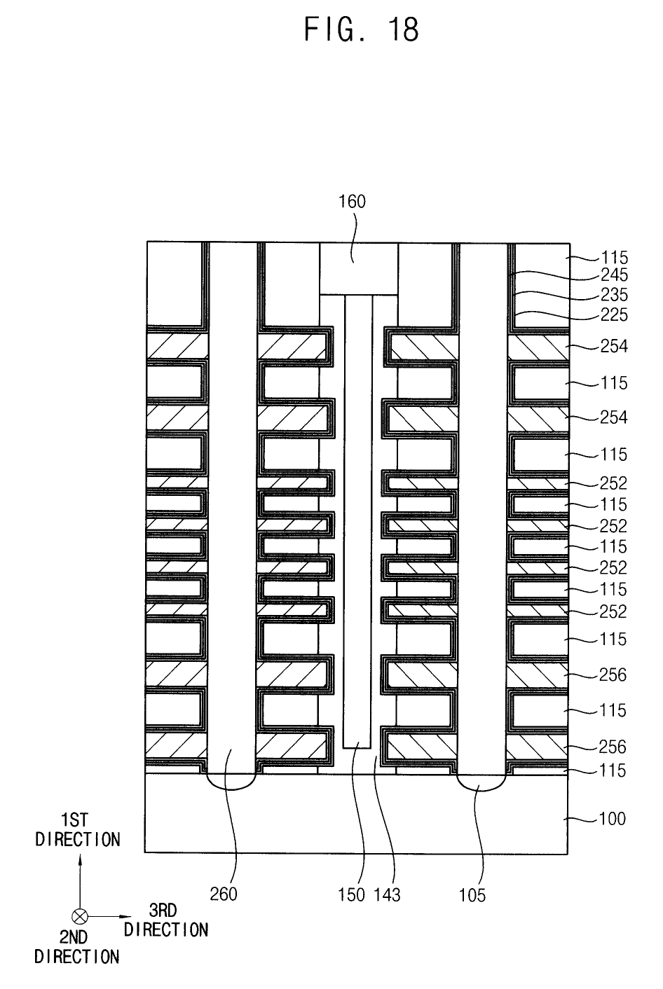

According to example embodiments, the sacrificial layer 120 at a level at which a GSL 256 (refer to FIG. 18) or an SSL 254 (refer to FIG. 18) may be formed may have a thickness greater than that of the sacrificial layer 120 at a level at which a word line 252 (refer to FIG. 18) may be formed. In one embodiment, the sacrificial layer 120 at a level at which a GSL 256 or an SSL 254 may be formed may have a thickness substantially equal to that of the sacrificial layer 120 at a level at which a word line 252 may be formed. The first insulation layer 110 adjacent to the sacrificial layer 120 at which the GSL 256 or the SSL 254 may be formed may have a thickness greater than that of the first insulation layer 110 adjacent to the sacrificial layer 120 at which the word line 252 may be formed. In one embodiment, the first insulation layer 110 adjacent to the sacrificial layer 120 at which the GSL 256 or the SSL 254 may be formed may have a thickness substantially equal to that of the first insulation layer 110 adjacent to the sacrificial layer 120 at which the word line 252 may be formed.

The number of the first insulation layer 110 and the number of the sacrificial layer 120 stacked on the substrate 100 may vary according to the desired number of the GSL 256, the word line 252 and the SSL 254. According to at least one example embodiment, each of the GSL 256 and the SSL 254 may be formed at 2 levels, and the word line 252 may be formed at 4 levels. The sacrificial layer 120 may be formed at 8 levels, and the first insulation layer 110 may be formed at 9 levels. According to at least one example embodiment, each of the GSL 256 and the SSL 254 may be formed at a single level, and the word line 252 may be formed at 2, 8 or 16 levels. In this case, the sacrificial layer 120 may be formed at 4, 10 or 18 levels, and the first insulation layer 110 may be formed at 5, 11 or 19 levels. However, the number of GSLs 256, SSLs 254 and word lines 252 is not limited herein.

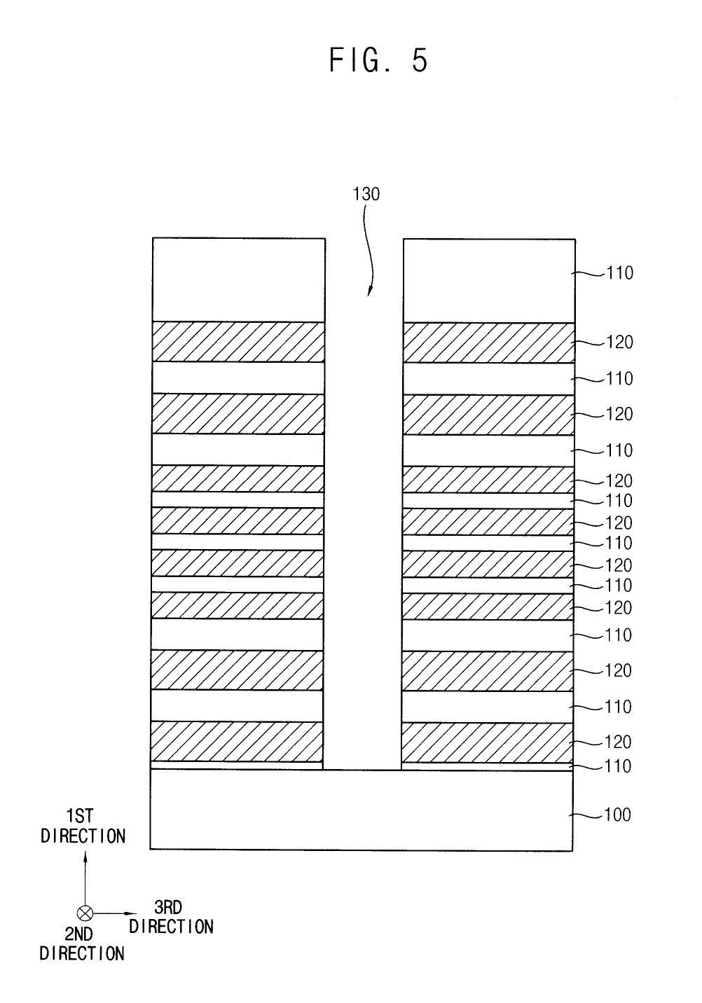

Referring to FIG. 5, a first opening 130 may be formed through the first insulation layers 110 and the sacrificial layers 120 to expose a top surface of the substrate 100.

According to example embodiments, after forming a hard mask (not shown) on an uppermost first insulation layer 110, the first insulation layers 110 and the sacrificial layers 120 may be dry etched using the hard mask as an etch mask to form the first opening 130. The first opening 130 may extend in a first direction substantially perpendicular to the top surface of the substrate 100. Due to the characteristics of a dry etch process, the first opening 130 may be of a width that becomes gradually smaller from a top portion to a bottom portion thereof.

According to example embodiments, a plurality of first openings 130 may be formed in a second direction substantially parallel to the top surface of the substrate 100 to define a first opening column, and a plurality of first opening columns may be formed in a third direction substantially perpendicular to the second direction to define a first opening array.

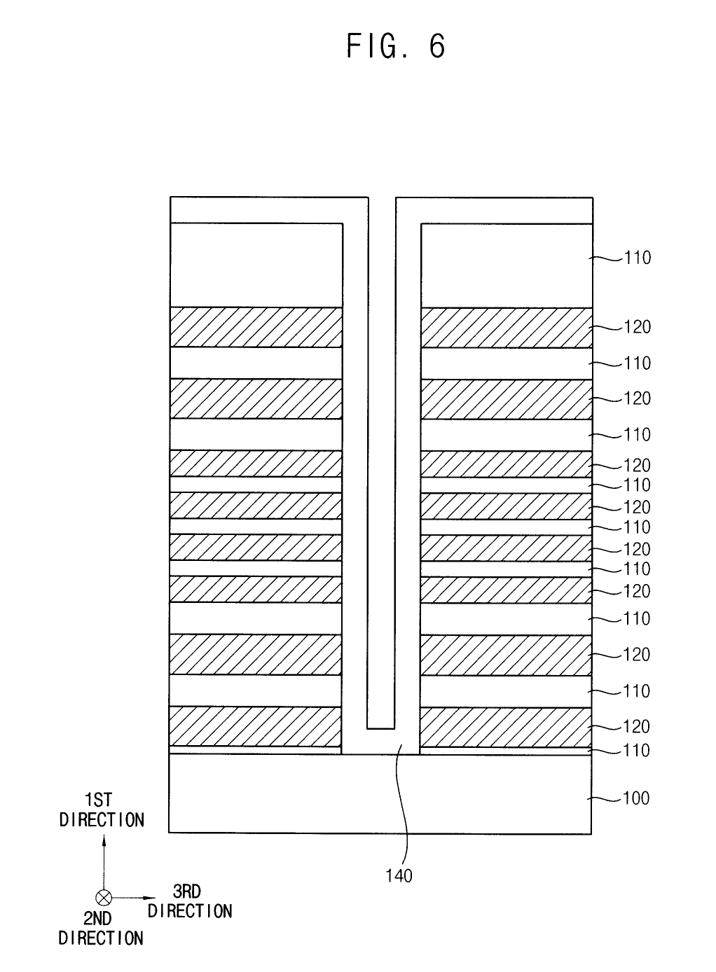

Referring to FIG. 6, a preliminary first channel layer 140 may be formed on a sidewall of the first opening 130 and on the exposed top surface of the substrate 100.

According to example embodiments, the preliminary first channel layer 140 may be formed to include, for example, doped polysilicon, single crystalline silicon and/or amorphous silicon.

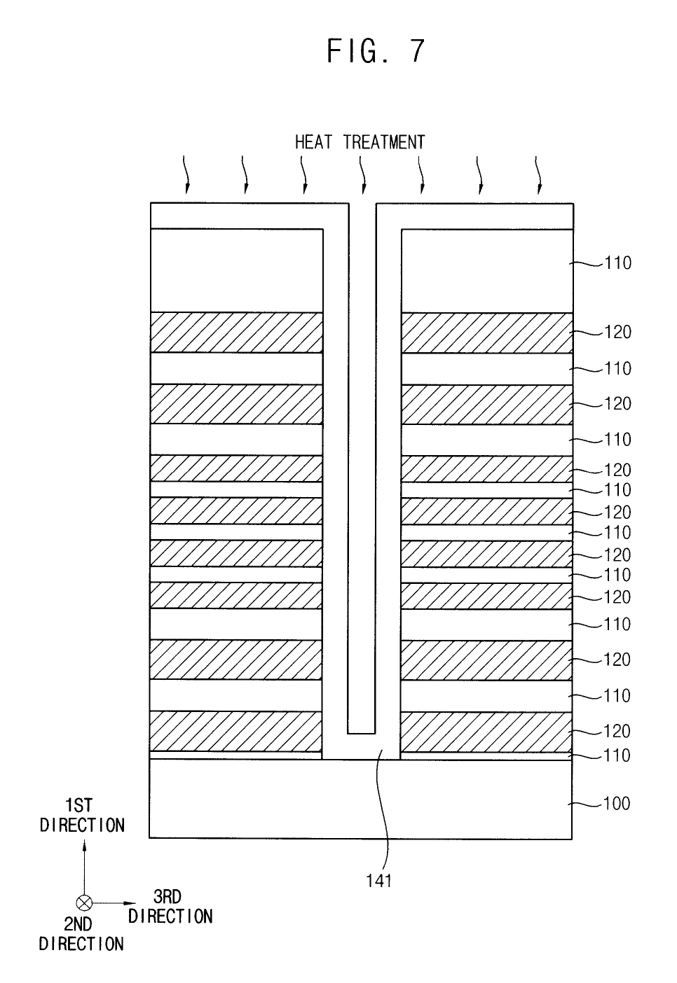

Referring to FIG. 7, a heat treatment may be performed on the preliminary first channel layer 140 to form a first channel layer 141.

By the heat treatment, the grain size of the polysilicon of the preliminary first channel layer 140 may be enlarged, or amorphous silicon of the preliminary first channel layer 140 may be transformed to polysilicon having a larger crystal. Thus, a transistor including the first channel layer 141 has a high saturation current.

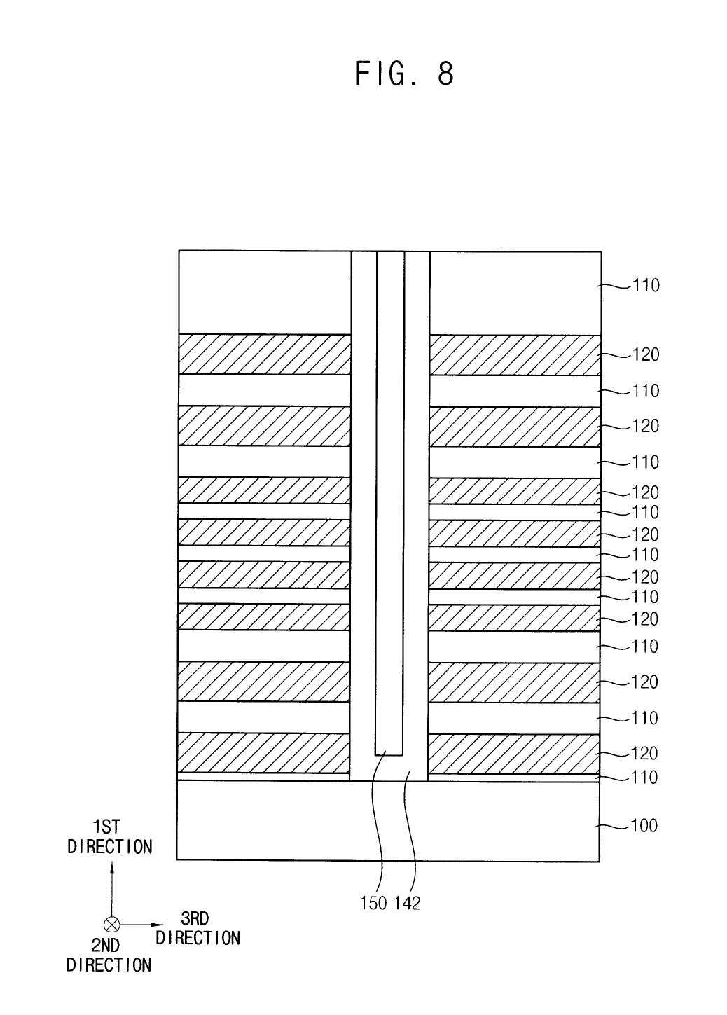

Referring to FIG. 8, a filling layer may be formed on the first channel layer 141 to sufficiently fill a remaining portion of the first opening 130. Upper portions of the filling layer and the first channel layer 141 may be planarized to form a filling layer pattern 150 and a first channel layer pattern 142, respectively. Thus, the first channel layer pattern 142 may have a hollow cylindrical shape, such as a cup shape. According to example embodiments, a plurality of first channel layer patterns 142 may be formed to define a first channel layer pattern column, and a plurality of first channel layer pattern columns may be formed to define a first channel layer pattern array. The planarization process may be performed by a CMP process.

Alternatively, a second channel layer pattern 148 may be formed to have a pillar shape instead of the hollow cylindrical shape.

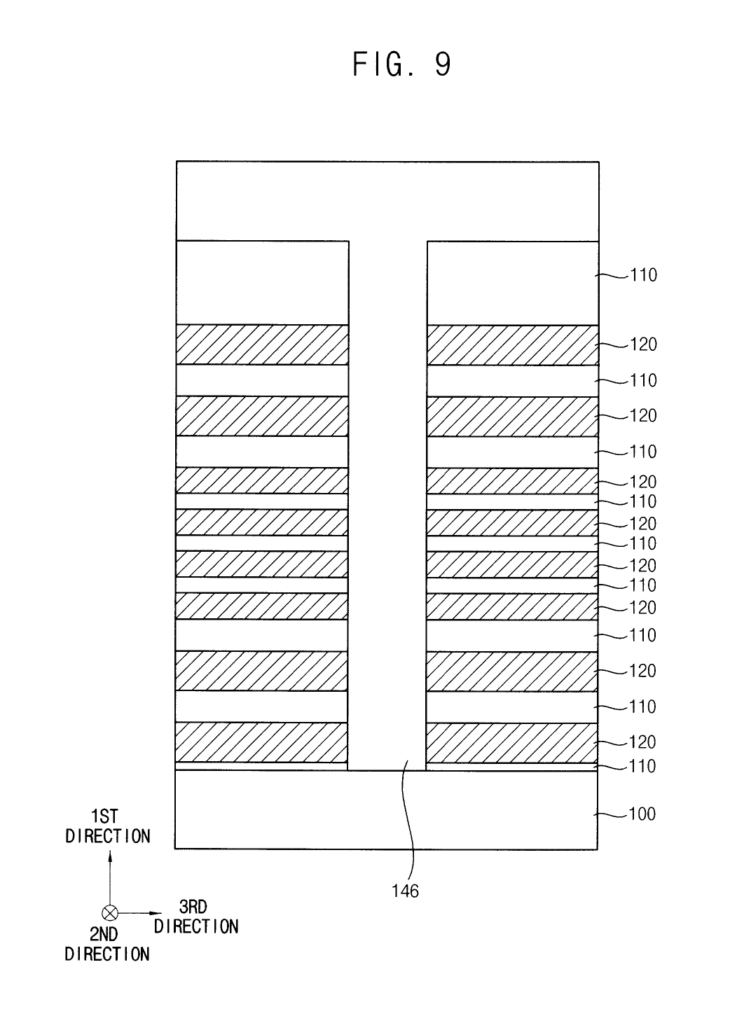

In one embodiment, referring to FIG. 9, a preliminary second channel layer 146 may be formed on the exposed top surface of the substrate 100 and the first insulation layer 110 to sufficiently fill the first opening 130. According to example embodiments, the preliminary second channel layer 146 may be formed to include, e.g., polysilicon or amorphous silicon.

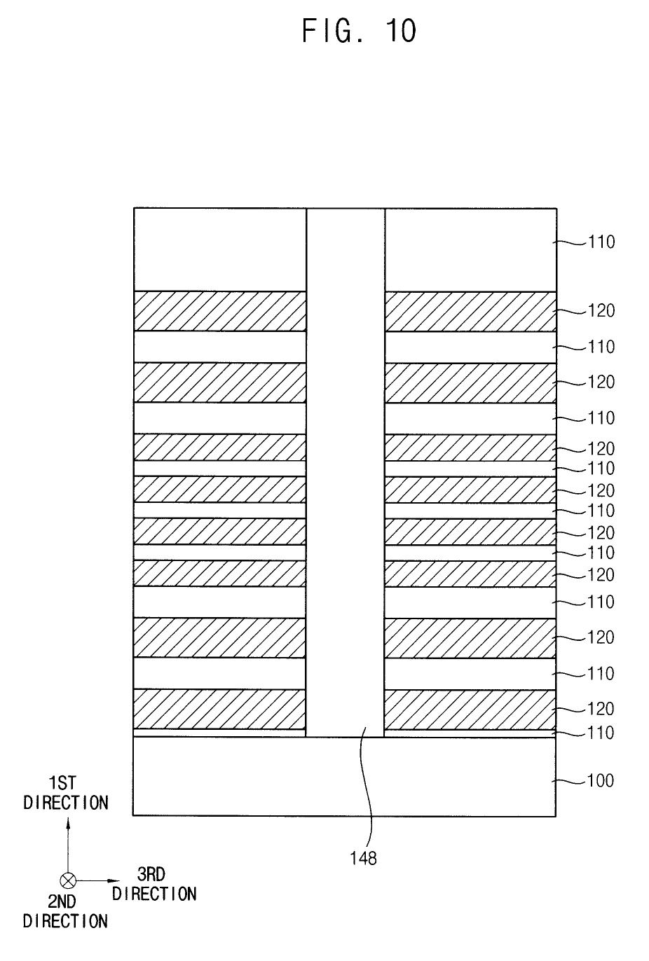

Referring to FIG. 10, a heat treatment may be performed on the preliminary second channel layer 146 to form a second channel layer including polysilicon of an enlarged grain size, and an upper portion of the second channel layer may be planarized until a top surface of the first insulation layer 110 is exposed to form a second channel layer pattern 148 filling the first opening 130. For example, the second channel layer pattern 148 may have a pillar shape. According to example embodiments, a plurality of second channel layer patterns 148 may be formed to define a second channel layer pattern column, and a plurality of second channel layer pattern columns may be formed to define a second channel layer pattern array.

Hereinafter, only the vertical memory device including the first channel layer pattern 142 of a cup shape is illustrated.

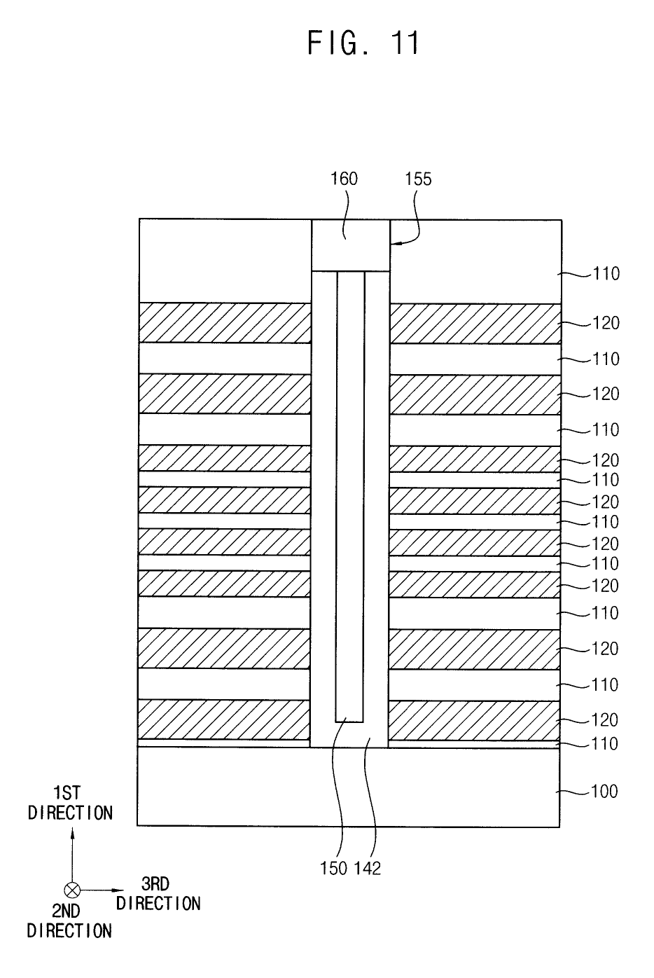

Referring to FIG. 11, upper portions of the filling layer pattern 150 and the first channel layer pattern 142 may be removed to form a recess 155, and a pad 160 may be formed on the first channel layer pattern 142 to fill the recess 155.

Particularly, the upper portions of the filling layer pattern 150 and the first channel layer pattern 142 may be removed by an etch back process to form the recess 155. A pad layer may be formed on the filling layer pattern 150, the first channel layer pattern 142 and the first insulation layer 110 to sufficiently fill the recess 155. An upper portion of the pad layer may be planarized until a top surface of the first insulation layer 110 is exposed to form the pad 160. According to example embodiments, the pad layer may be formed to include, e.g., amorphous silicon, polysilicon, or doped polysilicon. The planarization process may be performed by a CMP process.

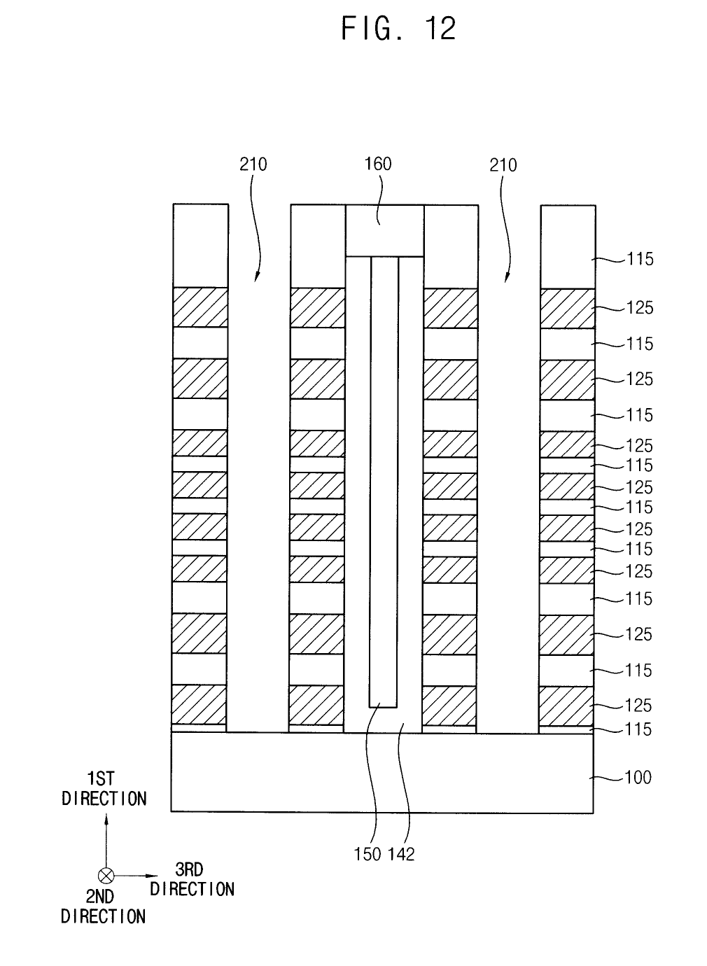

Referring to FIG. 12, a second opening 210 may be formed through the first insulation layers 110 and the sacrificial layers 120 to expose a top surface of the substrate 100.

According to example embodiments, after forming a hard mask (not shown) on the uppermost first insulation layer 110, the insulation layers 110 and the sacrificial layers 120 may be, for example, dry etched using the hard mask as an etch mask to form the second opening 210. The second opening 210 may extend in the first direction.

According to example embodiments, a plurality of second openings 210 may be formed in the third direction, and each second opening 210 may extend in the second direction. The first insulation layer 110 and the sacrificial layer 120 may be transformed into a first insulation layer pattern 115 and a sacrificial layer pattern 125, respectively. A plurality of first insulation layer patterns 115 and a plurality of sacrificial layer patterns 125 may be formed in the third direction at each level, and each first insulation layer pattern 115 and each sacrificial layer pattern 125 may extend in the second direction.

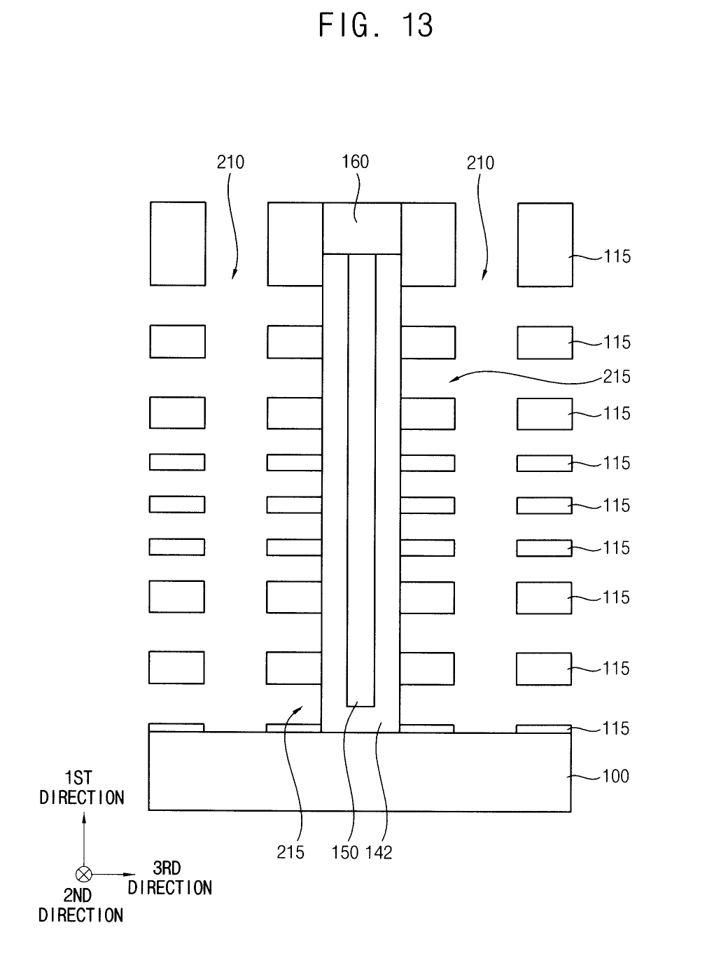

Referring to FIG. 13, the sacrificial layer patterns 125 may be removed to form a first gap 215 between the first insulation layer patterns 115 at adjacent levels. According to example embodiments, a plurality of first gaps 215 may be formed between the first insulation layer patterns 115, respectively. An outer sidewall of the first channel layer pattern 142 may be exposed by the first gap 215. According to example embodiments, the sacrificial layer patterns 125 exposed by the second opening 210 may be removed by, for example, a wet etch process using an etch solution including phosphoric acid and/or sulfuric acid.

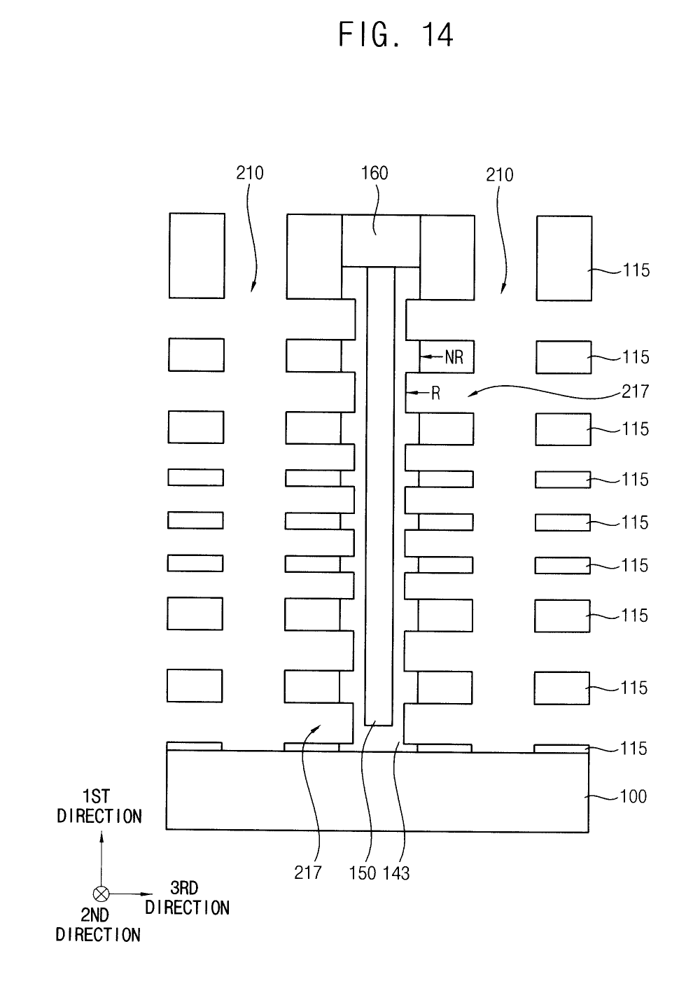

Referring to FIG. 14, portions of the outer sidewall of the first channel layer pattern 142 exposed by the first gap 215 may be partially removed so that a second gap 217 larger than the first gap 215 may be formed. For example, a recess R may be formed in the second gap 217 and a non-recess NR (e.g., extended portion) may be formed adjacent to the insulation layer pattern 115.

According to example embodiments, the portions of the outer sidewall of the first channel layer pattern 142 may be removed by a wet etching process using, e.g., SC1. Alternatively, the portions of the outer sidewall of the first channel layer pattern 142 may be removed by a dry etching process using, e.g., Cl₂ or NF₃.

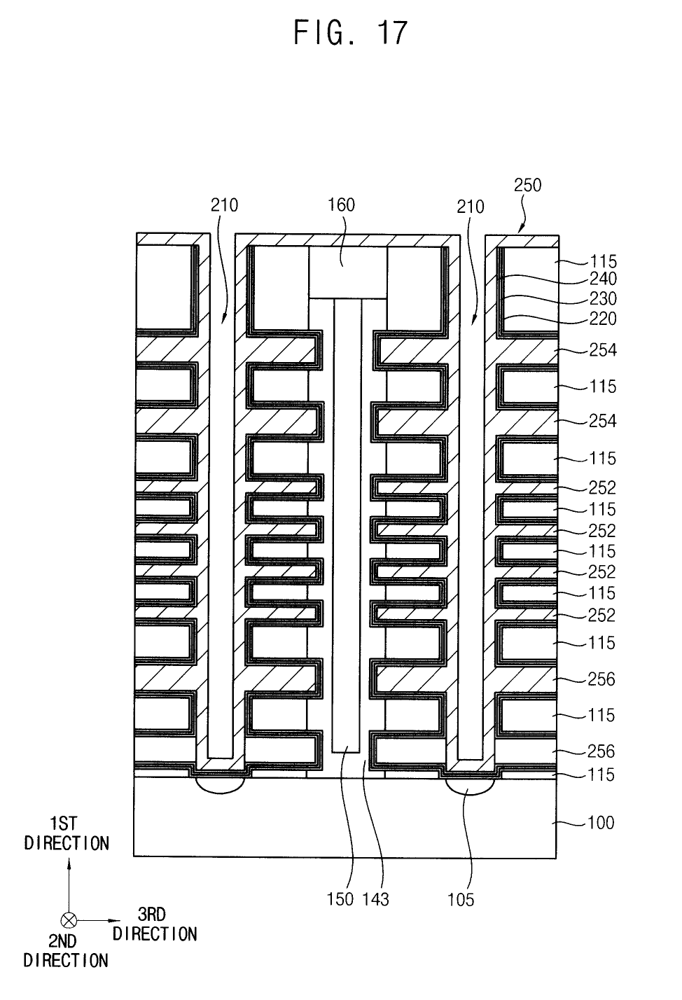

As the second gap 217 is formed, the first channel layer pattern 142 may be transformed to a first channel 143 having a thinner thickness at some portions. The first gap 215 or the second gap 217 may provide a space for forming a gate electrode layer 250 (refer to FIG. 17) serving as a GSL 256, a word line 252 and an SSL 254 (refer to FIGS. 17 and 18), and thus the gate electrode layer 250 may be formed to have a larger area in the second gap 217. Accordingly, the GSL 256, the word line 252 and the SSL 254 may have a low resistance. Additionally, the first channel 143 may have a relatively thin thickness at portions thereof adjacent to the GSL 256, the word line 252 and the SSL 254 so that the GSL 256, the word line 252 and the SSL 254 may have good swing characteristics.

In one embodiment, the first opening 130 may have a width that becomes gradually smaller from a top portion to a bottom portion thereof, so that the first channel layer pattern 142 may have a width that becomes gradually larger from a bottom portion to a top portion thereof. Thus, only an upper portion of the sidewall of the first channel layer pattern 142 adjacent to SSL 254 exposed by the first gap 215 may be removed so that the swing characteristics may be enhanced.

In one embodiment, referring to FIG. 15, an upper portion of the sidewall of the first channel layer pattern 142 exposed by a third gap 219 serving a space for subsequently forming the SSL 254 may be partially removed to form a third channel 144. The third gap 219 may be formed by additional mask pattern (not shown). Thus, the SSL 254 may have improved swing characteristics.

Hereinafter, only the vertical memory device having the first channel 143 is illustrated.

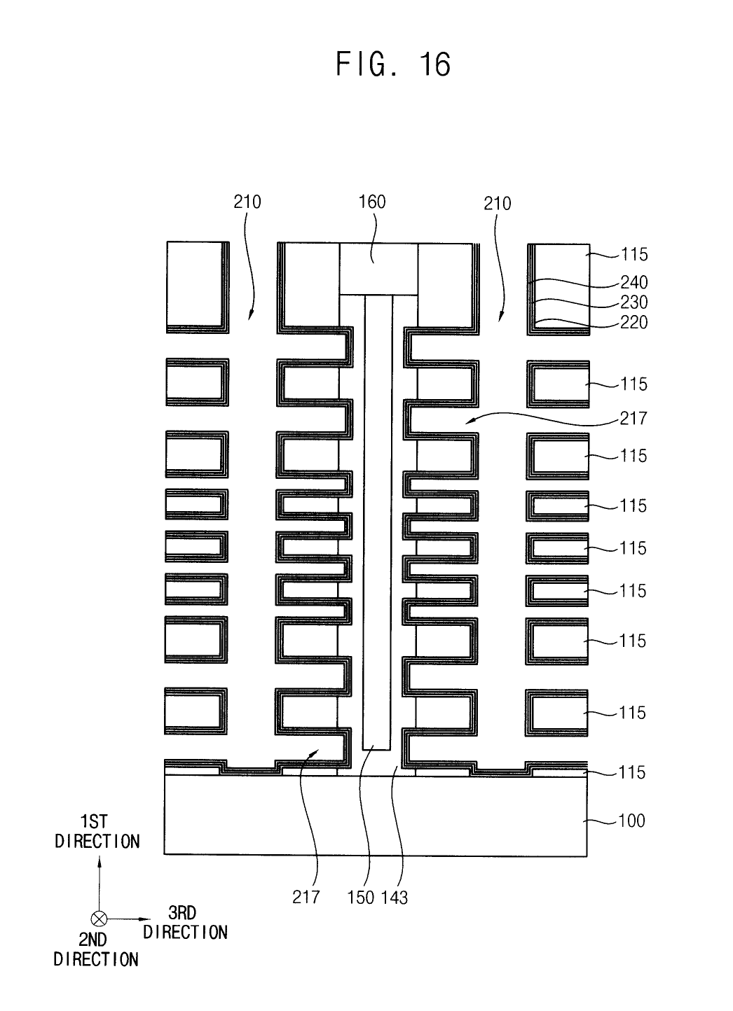

Referring to FIG. 16, a tunnel insulation layer 220, a charge trapping layer 230 and a blocking layer 240 may be sequentially formed on the exposed outer sidewall of the first channel 143, an inner wall of the second gap 217, a surface of the first insulation layer pattern 115, and the exposed top surface of the substrate 100.

According to example embodiments, the tunnel insulation layer 220 may be, for example, formed to include a silicon oxide by a CVD process. According to at least one example embodiment, the tunnel insulation layer 220 may be formed by a thermal oxidation on the exposed outer sidewall of the first channel 143 in the second gap 217. In this case, the tunnel insulation layer 220 may not be formed on the surface of the first insulation layer pattern 115.

The charge trapping layer 230 may be formed to include a nitride, for example, a silicon nitride and/or a metal oxide. The blocking layer 240 may be formed to include, for example, a silicon oxide and/or a metal oxide. For example, the metal oxide may include aluminum oxide, hafnium oxide, lanthanum oxide, lanthanum aluminum oxide, lanthanum hafnium oxide, hafnium aluminum oxide, titanium oxide, tantalum oxide and/or zirconium oxide. According to at least one example embodiment, the blocking layer 240 may be formed to be a multi-layered structure including a silicon oxide layer and a metal oxide layer.

Referring to FIG. 17, the gate electrode layer 250 may be formed on the blocking layer 240 to fill the second gap 217.

According to example embodiments, the gate electrode layer 250 may be formed to include a metal and/or a metal nitride. For example, the gate electrode layer 250 may be formed to include a metal and/or a metal nitride with a low electrical resistance, for example, tungsten, tungsten nitride, titanium, titanium nitride, tantalum, tantalum nitride and/or platinum. According to at least one example embodiment, the gate electrode layer 250 may be formed to be a multi-layered structure of a barrier layer including a metal nitride and a metal layer including a metal.

The gate electrode layer 250 may be formed by, for example, a CVD process and/or an ALD process, and the second opening 210 may be partially filled.

Referring to FIG. 18, the gate electrode layer 250 may be partially removed to form the GSL 256, the word line 252 and the SSL 254 in the second gaps 217. According to example embodiments, the gate electrode layer 250 may be partially removed by, for example, a wet etch process.

Each of the GSL 256, the word line 252 and the SSL 254 may be formed at a single level or at a plurality of levels. According to at least one example embodiment, each of the GSL 256 and the SSL 254 may be formed at 2 levels, and the word line 252 may be formed at 4 levels between the GSL 256 and the SSL 254. However, the number of GSLs 256, word lines 252 and SSLs 254 is not limited.

When the gate electrode layer 250 is partially removed, portions of the blocking layer 240, the charge trapping layer 230 and the tunnel insulation layer 220 on top surfaces and bottom surfaces of the first insulation layer pattern 115, and on the substrate 100 may also be removed to form a blocking layer pattern 245, a charge trapping layer pattern 235 and a tunnel insulation layer pattern 225, respectively. According to at least one example embodiment, portions of the blocking layer 240, the charge trapping layer 230 and the tunnel insulation layer 220 on a sidewall of the first insulation layer pattern 115 may be also removed so that the blocking layer pattern 245, the charge trapping layer pattern 235 and the tunnel insulation layer pattern 225 may be formed only on the inner wall of the second gap 217.

In a process in which the gate electrode layer 250, the blocking layer 240, the charge trapping layer 230 and the tunnel insulation layer 220 are partially removed, a third opening (not shown) exposing a top surface of the substrate 100 and extending in the second direction may be formed, and impurities may be implanted into the exposed top surface of the substrate 100 to form an impurity region 105. According to example embodiments, the impurities may include n-type impurities, for example, phosphorus and/or arsenic. According to example embodiments, the impurity region 105 may extend in the second direction and serve as a CSL.

A metal silicide pattern (not shown), e.g., a cobalt silicide pattern may be further formed on the impurity region 105.

A second insulation layer pattern 260 filling the third opening may be formed. According to example embodiments, after a second insulation layer filling the third opening is formed on the substrate 100 and the first insulation layer pattern 115, the second insulation layer may be planarized until a top surface of the first insulation layer pattern 115 is exposed to form the second insulation layer pattern 260.

Referring to FIG. 1C again, a third insulation layer 270 may be formed on the first and second insulation layer patterns 115 and 260, the pad 160, the blocking layer pattern 245, the charge trapping layer pattern 235 and the tunnel insulation layer pattern 225, and a fourth opening (not shown) may be formed to expose a top surface of the pad 160. According to example embodiments, a plurality of fourth openings corresponding to the first channels 143 and the pads 160 may be formed in the second direction to form a fourth opening column, and a plurality of fourth opening columns may be formed in the third direction to form a fourth opening array.

A bit line contact 280 may be formed on the pad 160 to fill the fourth opening. The bit line contact 280 may be formed to include, for example, a metal, a metal nitride and/or doped polysilicon. A bit line 290 electrically connected to the bit line contact 280 may be formed to complete the vertical memory device. The bit line 290 may be formed to include, for example, a metal, a metal nitride and/or doped polysilicon. According to example embodiments, a plurality of bit lines 290 may be formed in the second direction, and each bit line 290 may be formed to extend in the third direction.

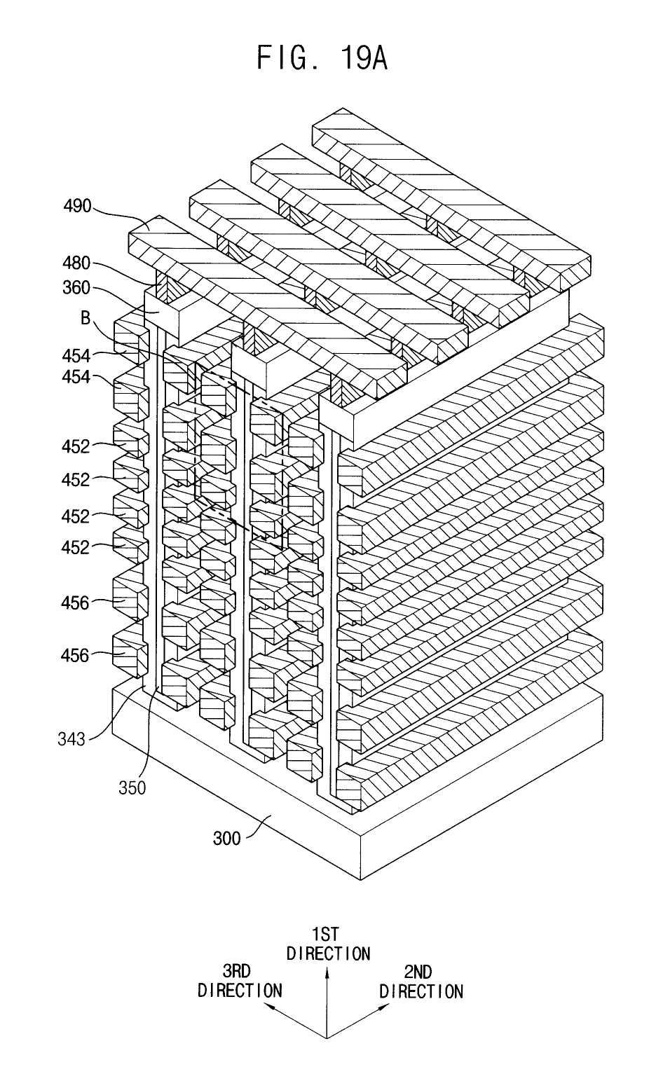

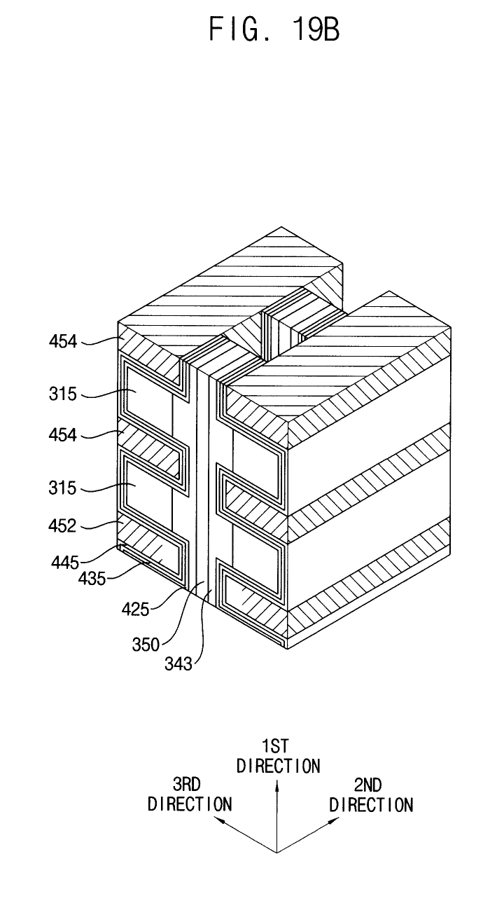

FIGS. 19A and 19B are a perspective diagram and a local perspective diagram, respectively, illustrating vertical memory devices in accordance with still other example embodiments. FIG. 19B may be a local perspective view of region B of the vertical memory device in FIG. 19A. The vertical memory device may be substantially the same as that of FIGS. 1A, 1B and 1C, except that the vertical memory device may include an insulation layer pattern, and the shapes of a filling layer pattern be different from that of the filling layer pattern of FIG. 1, and thus repetitive explanations may be omitted herein.

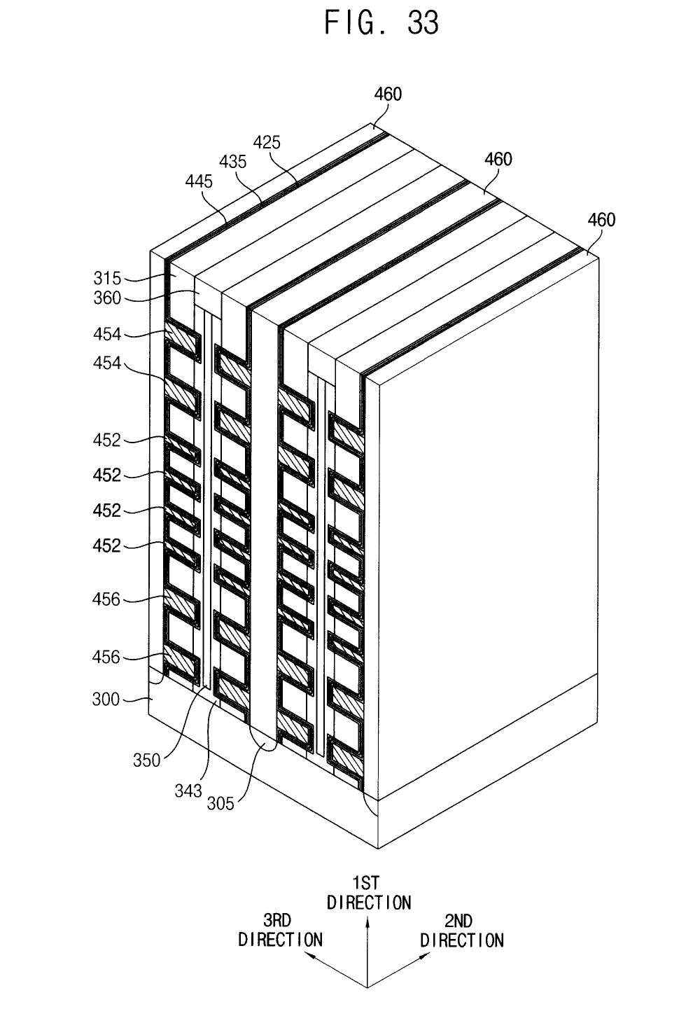

Referring to FIGS. 19A and 19B, a vertical memory device may include a GSL 456, a word line 452 and an SSL 454 that are spaced apart from each other along a first direction substantially perpendicular to a top surface of a substrate 300, and a fourth channel 343 on first sidewalls of the GSL 456, the word line 452 and the SSL 454 along the first direction. The vertical memory device may further include a bit line 490 electrically connected to the fourth channel 343, and an impurity region 305 (see FIG. 33) serving as a CSL.

Each of the GSL 456, the word line 452 and the SSL 454 may be at a single level (e.g., one of each, each at a different height) or more than one level, and a first insulation layer pattern 315 may be interposed therebetween. According to at least one example embodiment, the GSL 456 and the SSL 454 may be at 2 levels (e.g., two of each at different heights), respectively, and the word line 452 may be at 4 levels between the GSL 456 and the SSL 454. However, the GSL 456 and the SSL 454 may be at one level, and the word line 452 may be formed at 2, 8 or 16 levels. According to example embodiments, each of the GSL 456, the word line 452 and the SSL 454 may extend in the second direction, and a plurality of GSLs 456, a plurality of word lines 452, and a plurality of SSLs 454 may be in the third direction. The GSL 456, the word line 452 and the SSL 454 may have a thickness thicker than that of the first insulation layer pattern 315 along the third direction.

The fourth channel 343 may have a linear and/or bar shape extending in the first direction, and may be on the GSL 456, the word line 452 and the SSL 454, and on a sidewall of the first insulation layer patterns 315 therebetween.

A portion of the fourth channel 343 adjacent to the GSL 456, the word line 452 and the SSL 454 may have a thickness smaller than a portion of the fourth channel 343 adjacent to the first insulation layer pattern 315. According to example embodiments, the fourth channel 343 may have a plurality of recesses R at lateral portions adjacent to the GSL 456, the word line 452 and the SSL 454.

According to example embodiments, a plurality of fourth channels 343 may be formed in the second direction to define a fourth channel column, and a plurality of fourth channel columns may be formed in a third direction substantially perpendicular to the second direction to define a fourth channel array.

A filling layer pattern 350 of a pillar shape may be in a space between the fourth channels 343 with the linear shape adjacent to each other in the third direction, particularly, between second sidewalls of the fourth channels 343 on which the GSL 456, the word line 452 and the SSL 454 are not included, and the fourth channels 343 may be connected to each other between the filling layer pattern 350 and the substrate 300. The filling layer pattern 350 may include an insulating material, for example, an oxide.

A pad 360 may be on the filling layer pattern 350 and the fourth channel 343, and may electrically connect the fourth channel 343 to a bit line contact 480.

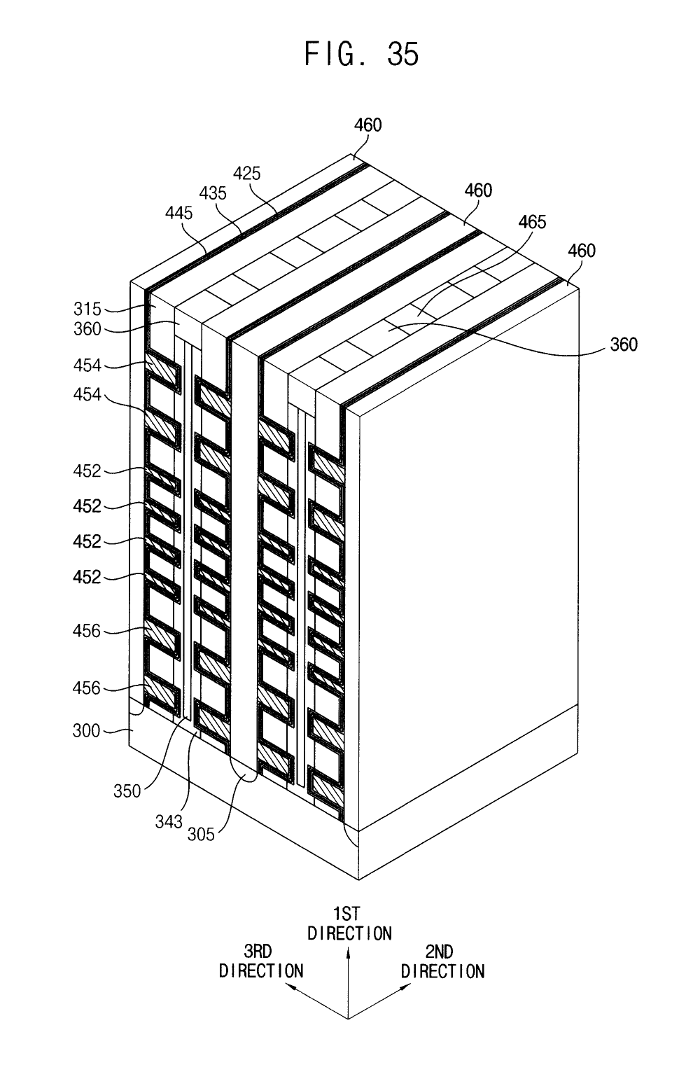

A plurality of structures each of which may include two fourth channels 343, the filling layer pattern 350 and the pad 360 may be insulated from each other by a third insulation layer pattern 465 (see FIG. 35) in the second direction. The third insulation layer pattern 465 may be of a pillar shape extending in the first direction. According to example embodiments, a plurality of third insulation layer patterns may be in the second direction to define a third insulation layer pattern column, and a plurality of third insulation layer pattern columns may be formed in the third direction to define a third insulation layer pattern array.

A tunnel insulation layer pattern 425, a charge trapping layer pattern 435 and a blocking layer pattern 445 may be between each of the GSL 456, the word line 452 and the SSL 454, and a first sidewall of the fourth channel 343 in the third direction. The tunnel insulation layer pattern 425, the charge trapping layer pattern 435 and the blocking layer pattern 445 may be between each of the GSL 456, the word line 452 and the SSL 454, and the first insulation layer pattern 315 and/or on a sidewall of the first insulation layer pattern 315. According to at least one example embodiment, the tunnel insulation layer pattern 425 may be only on the first sidewall of the fourth channel 343.

A second insulation layer pattern 460 (see FIG. 33) may be formed between structures each of which may include the GSL 456, the word line 452 and the SSL 454 extending in the second direction and the first insulation layer pattern 315 therebetween. The impurity region 305 (refer to FIG. 33) may be at an upper portion of the substrate 300 beneath the second insulation layer pattern 460, which may extend in the second direction and serve as a CSL.

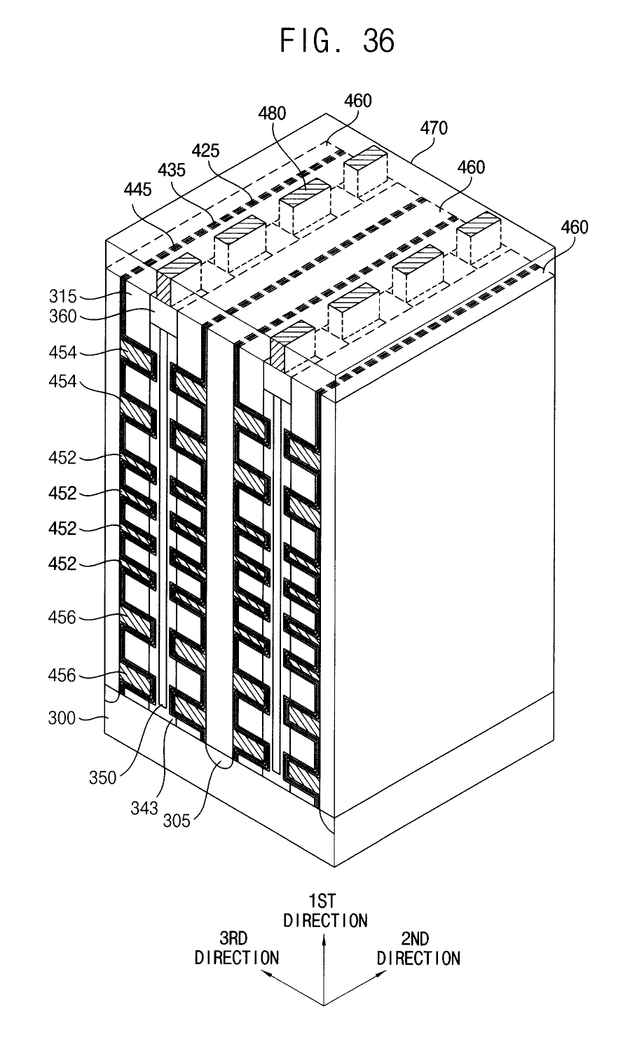

The bit line 490 may be electrically connected to the pad 360 via the bit line contact 480, and may be electrically connected to the fourth channel 343. According to example embodiments, the bit line 490 may extend in the third direction. The bit line contact 480 may be contained in a fourth insulation layer 470 (refer to FIG. 36), and contact the pad 360. The fourth insulation layer 470 may be formed on the first, second and third insulation layer patterns 315, 460 and 465, the fourth channel 343, the pad 360, the blocking layer pattern 445, the charge trapping layer pattern 435 and the tunnel insulation layer pattern 425.

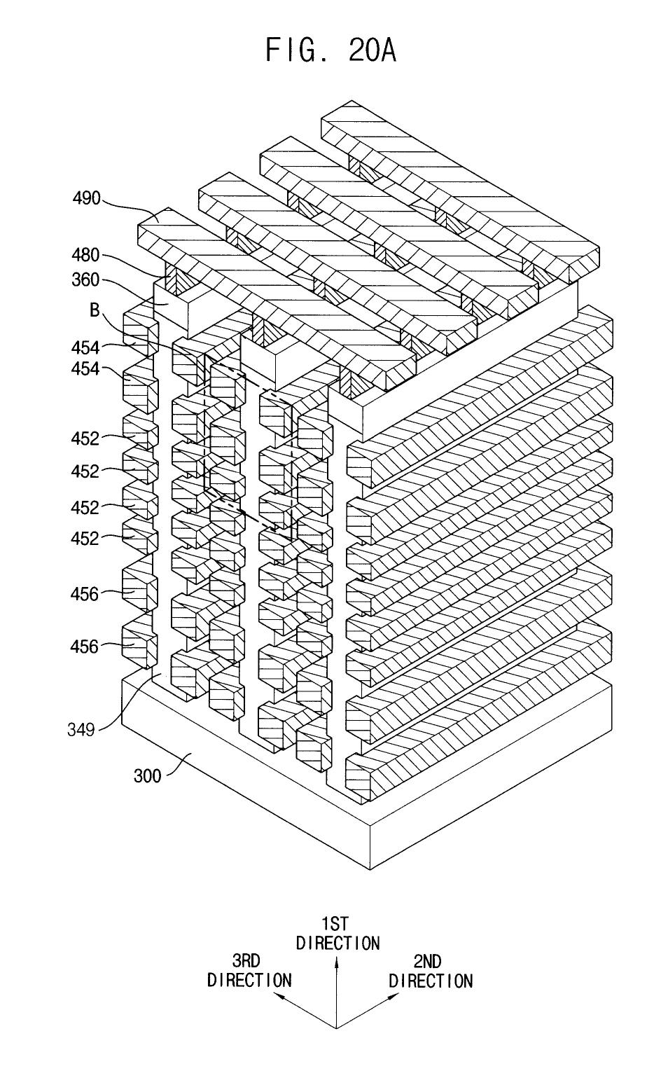

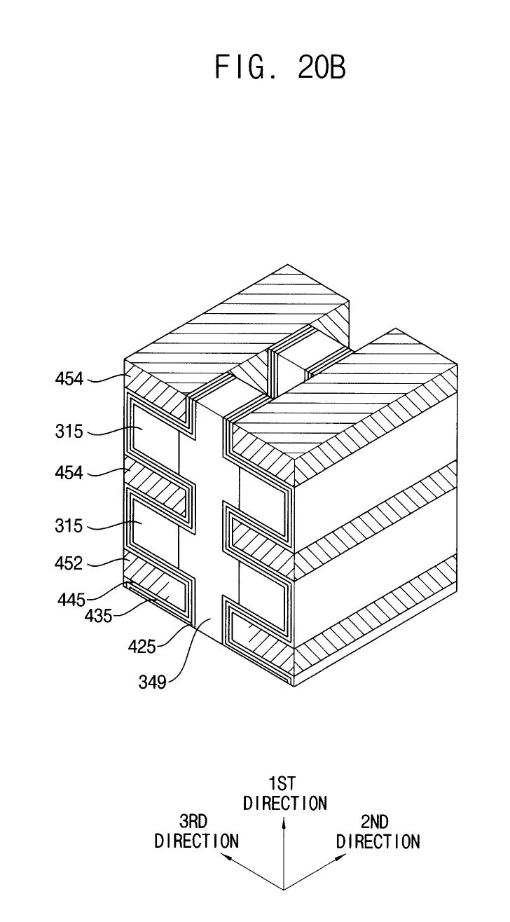

FIGS. 20A and 20B are a local perspective diagram and a cross-sectional view, respectively, illustrating vertical memory devices in accordance with still other example embodiments. The vertical memory devices may be substantially the same as those illustrated with reference to FIGS. 19A and 19B except for a filling layer pattern and the shape of a channel, and thus brief explanations are provided herein.

A fifth channel 349 may have a pillar shape extending in the first direction, and may be on the GSL 456, the word line 452 and the SSL 454, and on a sidewall of the first insulation layer patterns 315 therebetween. Thus, the vertical memory devices may not have a filling layer pattern.

The fifth channel 349 may have a thickness that is thinner at a portion thereof adjacent to the GSL 456, the word line 452 and the SSL 454 than a thickness at a portion thereof adjacent to the first insulation layer pattern 315. According to example embodiments, the fifth channel 349 may have a plurality of recesses R at lateral portions adjacent to the GSL 456, the word line 452 and the SSL 454.

According to example embodiments, a plurality of fifth channels 349 may be formed in the second direction to define a fifth channel column, and a plurality of fifth channel columns may be formed in a third direction substantially perpendicular to the second direction to define a fifth channel array.

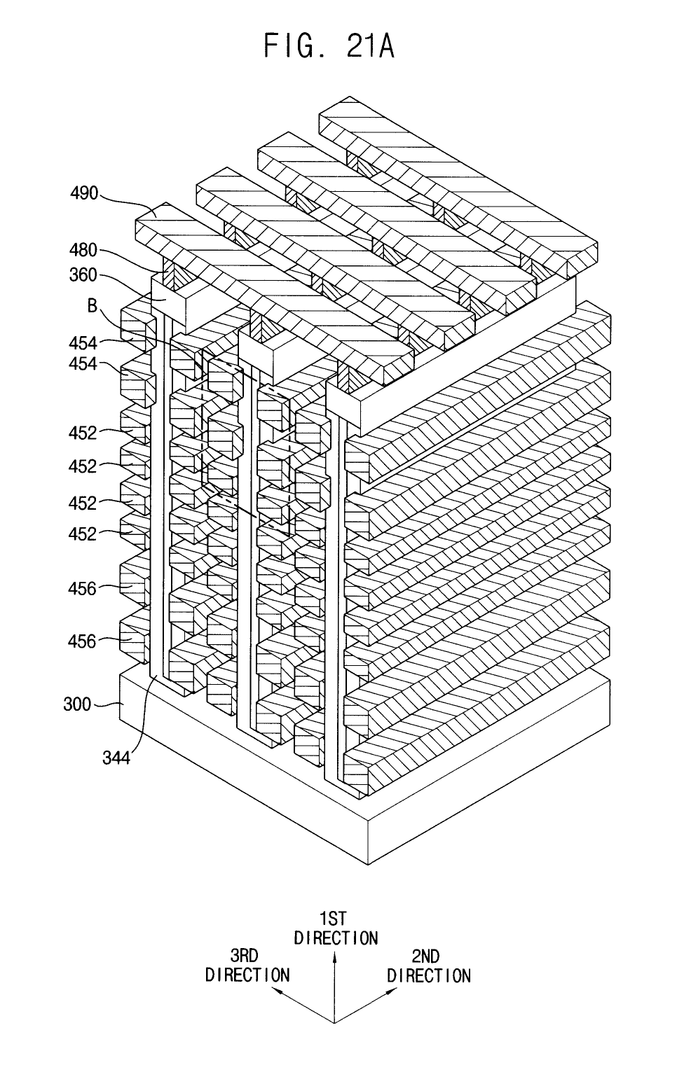

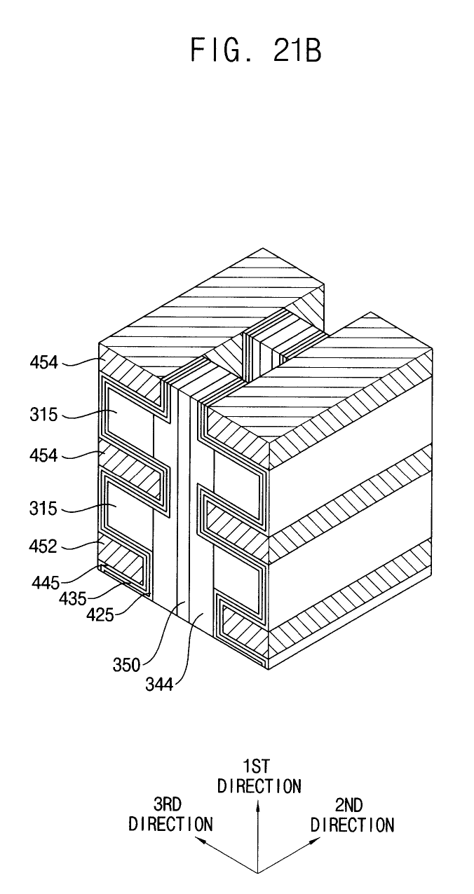

FIGS. 21A and 21B are a local perspective diagram and a cross-sectional view, respectively, illustrating vertical memory devices in accordance with still other example embodiments. The vertical memory devices may be substantially the same as those illustrated with reference to FIGS. 19A and 19B except for the shape of a channel, and thus brief explanations are provided herein.

A sixth channel 344 may have a pillar shape extending in the first direction, and may be on the GSL 456, the word line 452 and the SSL 454, and on a sidewall of the first insulation layer patterns 315 therebetween. The vertical memory devices may have a filling layer pattern 350 in a space between the sixth channels 344 with the linear shape adjacent to each other in the third direction, particularly, between second sidewalls of the sixth channels 344 on which the GSL 456, the word line 452 and the SSL 454 are not included, and the sixth channels 344 may be connected to each other between the filling layer pattern 350 and the substrate 300. The filling layer pattern 350 may include an insulating material, for example, an oxide.

The sixth channel 344 may have a thickness that is thinner at a portion thereof adjacent to the SSL 454 than a thickness at a portion thereof adjacent to the first insulation layer pattern 315. Unlike the fourth channel 343, a thickness of a portion of the sixth channel 344 adjacent to the GSL 456 and the word line 452 may be substantially the same as a thickness of a portion of the sixth channel 344 adjacent to the first insulation layer pattern 315, and thus only the thickness of the portion of the sixth channel 344 adjacent to the SSL 454 may be thinner than the thickness at a portion thereof adjacent to the first insulation layer pattern 315. According to example embodiments, the sixth channel 344 may have a recess R at a lateral portion adjacent to the SSL 454.

According to example embodiments, a plurality of sixth channels 344 may be formed in the second direction to define a sixth channel column, and a plurality of sixth channel columns may be formed in the third direction to define a sixth channel array.

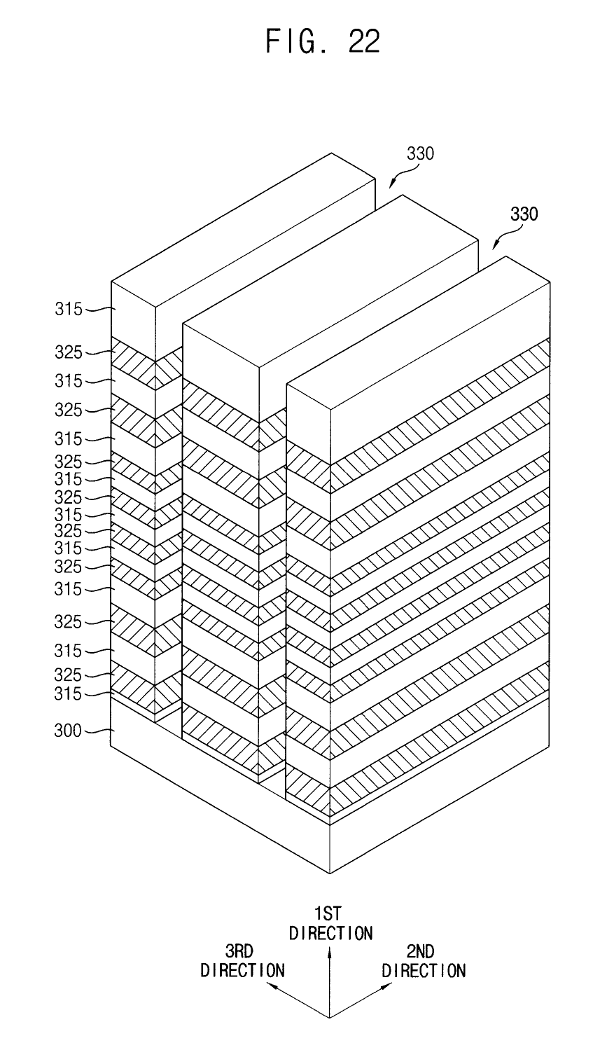

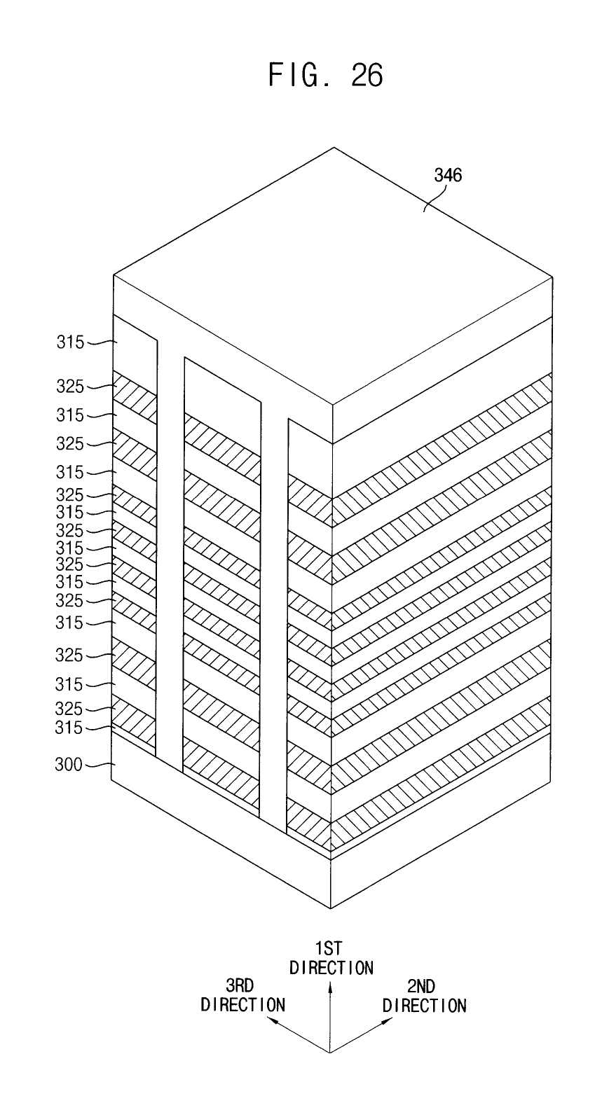

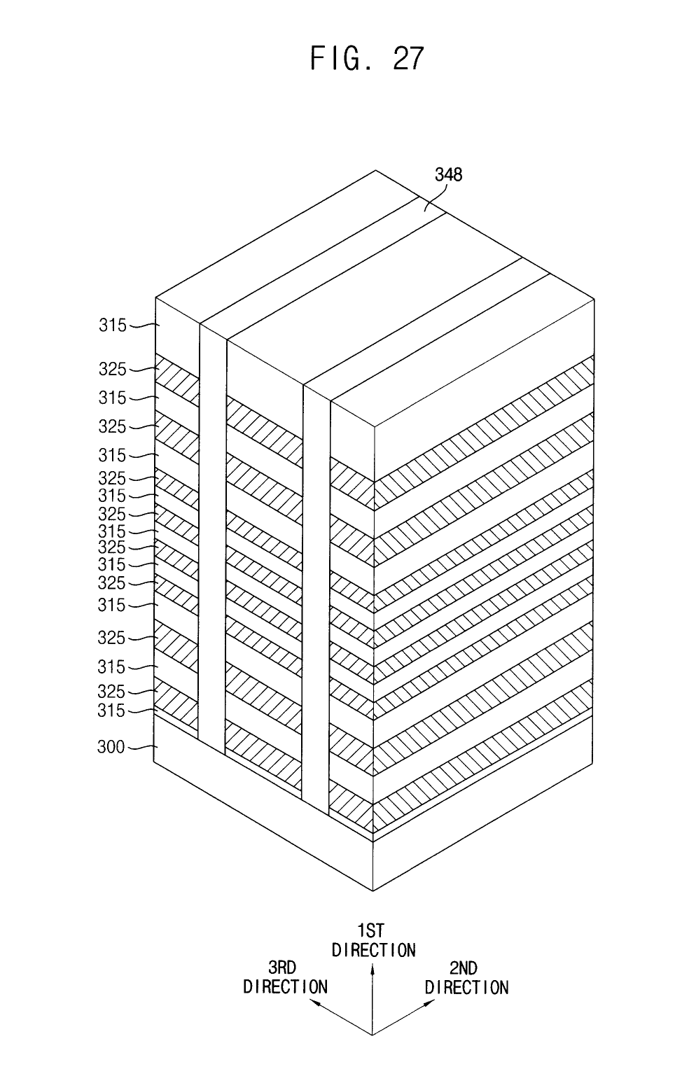

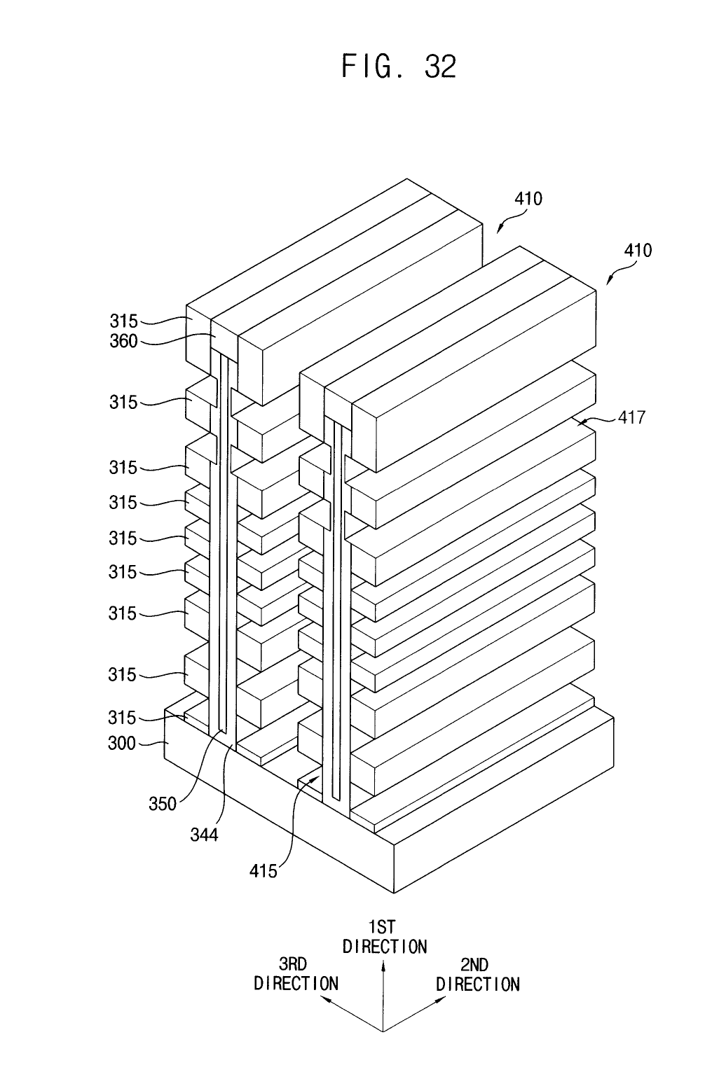

FIGS. 22-37 are perspective diagrams illustrating methods of manufacturing vertical memory devices of FIGS. 19-21 in accordance with example embodiments. Particularly, FIGS. 22-25, 28-31 and 33-37 are perspective diagrams illustrating methods of manufacturing the vertical memory device of FIG. 19, FIGS. 26-27 are perspective diagrams illustrating methods of manufacturing the vertical memory device of FIG. 20, and FIG. 32 is perspective diagrams illustrating methods of manufacturing the vertical memory device of FIG. 21. The method may include processes substantially the same as or similar to those of FIGS. 4-18 except for forming an insulation layer pattern and the shape of a channel, and thus detail explanations may be omitted herein.

Referring to FIG. 22, processes substantially the same as or similar to those illustrated with reference to FIGS. 4 and 5 may be performed. A first insulation layer and a sacrificial layer may be alternately and repeatedly formed on a substrate 300, and a first opening 330 extending in a first direction substantially perpendicular to a top surface of the substrate 300 may be formed through the first insulation layer and the sacrificial layer to expose a top surface of the substrate 300.

The first opening 330 may not be of an island shape but may extend in a second direction substantially parallel to the top surface of the substrate 300. According to example embodiments, a plurality of first openings 330 may be formed in a third direction substantially perpendicular to the second direction. The first insulation layer and the sacrificial layer may be transformed into a first insulation layer pattern 315 and a sacrificial layer pattern 325. Each first insulation layer pattern 315 and each sacrificial layer pattern 325 in each level may extend in the second direction. According to example embodiments, a plurality of first insulation layer patterns 315 and a plurality of sacrificial layer patterns 325 may be formed in the third direction at each level (e.g., each level or height may include one of the first insulation layer patterns 315 and sacrificial layer patterns 325).

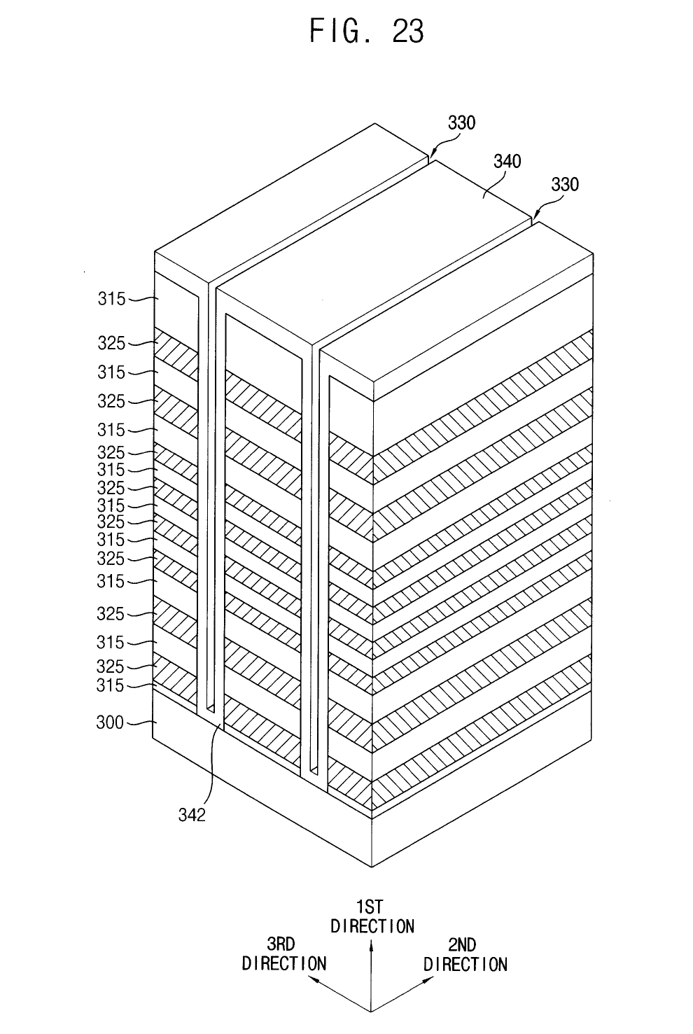

Referring to FIG. 23, a process substantially the same as or similar to that illustrated with reference to FIG. 6 may be performed. A preliminary fourth channel layer 340 may be formed on an inner wall of the first opening 330 and the exposed top surface of the substrate 300. According to example embodiments, the preliminary fourth channel layer 340 may be formed to include polysilicon or amorphous silicon.

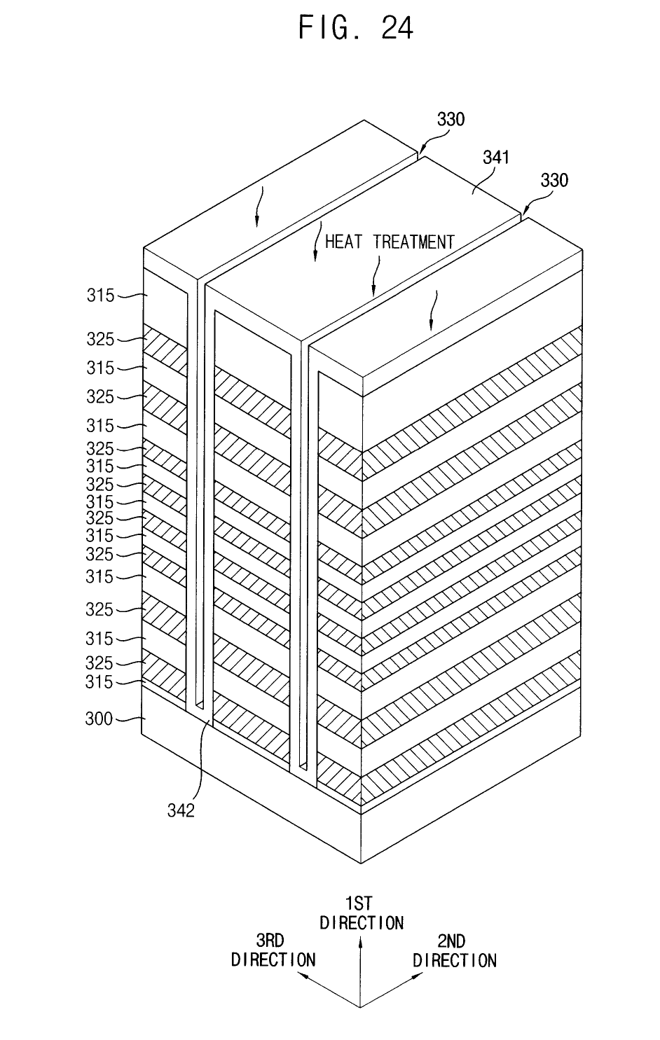

Referring to FIG. 24, a process substantially the same as or similar to that illustrated with reference to FIG. 7 may be performed.

That is, a heat treatment may be performed on the preliminary fourth channel layer 340 to form a fourth channel layer 341.

By the heat treatment, the grain size of the polysilicon of the preliminary fourth channel layer 340 may be enlarged, or amorphous silicon of the preliminary fourth channel layer 340 may be transformed to polysilicon having a larger crystal.

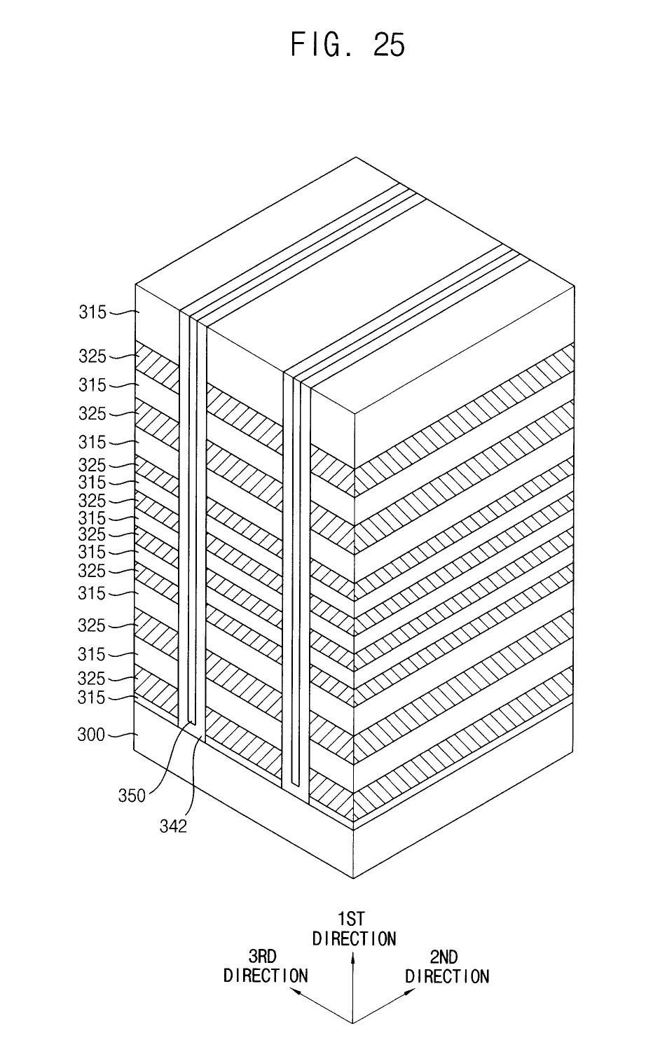

Referring to FIG. 25, a process substantially the same as or similar to that illustrated with reference to FIG. 8 may be performed.

Thus, a fourth channel layer pattern 342 having a liner and/or bar shape may be formed on both sidewalls of the first opening 330, and a filling layer pattern 350 may be formed on the fourth channel layer pattern 342 to fill a remaining portion of the first opening 330.

Alternatively, the filling layer pattern 350 may not be formed.

In one embodiment, referring to FIG. 26, a preliminary fifth channel layer 346 may be formed on the exposed top surface of the substrate 300 and the first insulation layer pattern 315 to sufficiently fill the first opening 330. According to example embodiments, the preliminary fifth channel layer 346 may be formed to include, e.g., polysilicon or amorphous silicon.

Referring to FIG. 27, a heat treatment may be performed on the preliminary fifth channel layer 346 to form a fifth channel layer including polysilicon of an enlarged grain size, and an upper portion of the fifth channel layer may be planarized until a top surface of the first insulation layer pattern 315 is exposed to form a fifth channel layer pattern 348 filling the first opening 330. Thus, the fifth channel layer pattern 348 may have a pillar shape.

Hereinafter, only the vertical memory device including the fourth channel layer pattern 342 and the filling layer pattern 350 is illustrated.

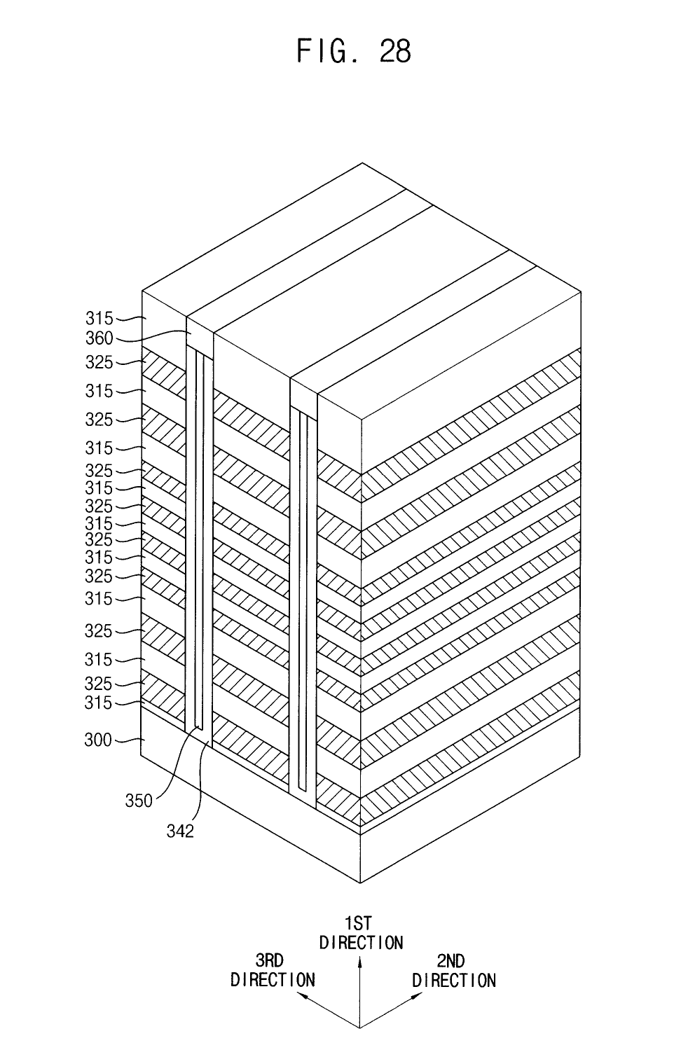

Referring to FIG. 28, a process substantially the same as or similar to that illustrated with reference to FIG. 11 may be performed.

That is, upper portions of the filling layer pattern 350 and the fourth channel layer pattern 342 may be removed to form a recess (not shown), and a pad 360 may be formed on the fourth channel layer pattern 342 and the filling layer pattern 350 to fill the recess.

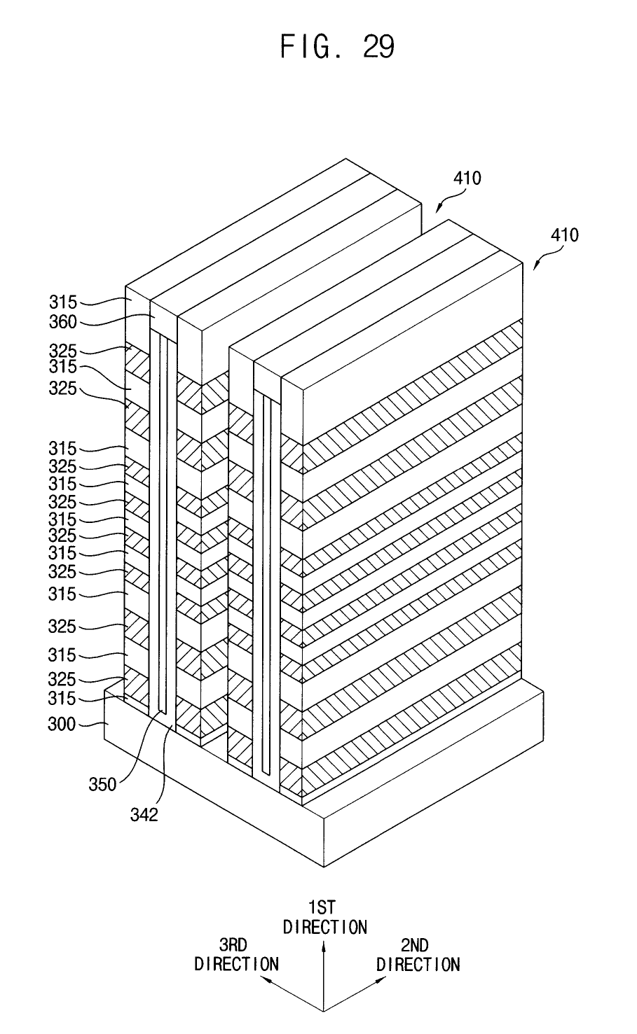

Referring to FIG. 29, a process substantially the same as or similar to that illustrated with reference to FIG. 12 may be performed.

Accordingly, a second opening 410 may be formed through the first insulation layer pattern 315 and the sacrificial layer pattern 325 to expose a top surface of the substrate 300. According to example embodiments, a plurality of second openings 410 may be formed in the third direction, and each second opening 410 may extend in the second direction.

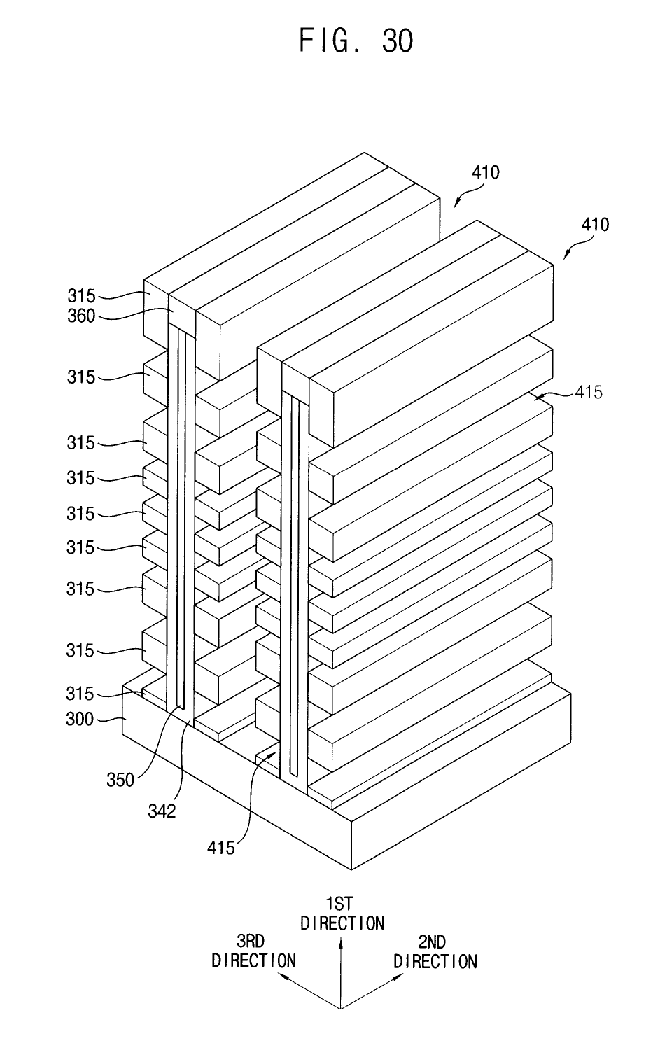

Referring to FIG. 30, a process substantially the same as or similar to that illustrated with reference to FIG. 13 may be performed. The sacrificial layer pattern 325 may be removed to form a first gap 415 between the first insulation layer patterns 315 at a plurality of levels.

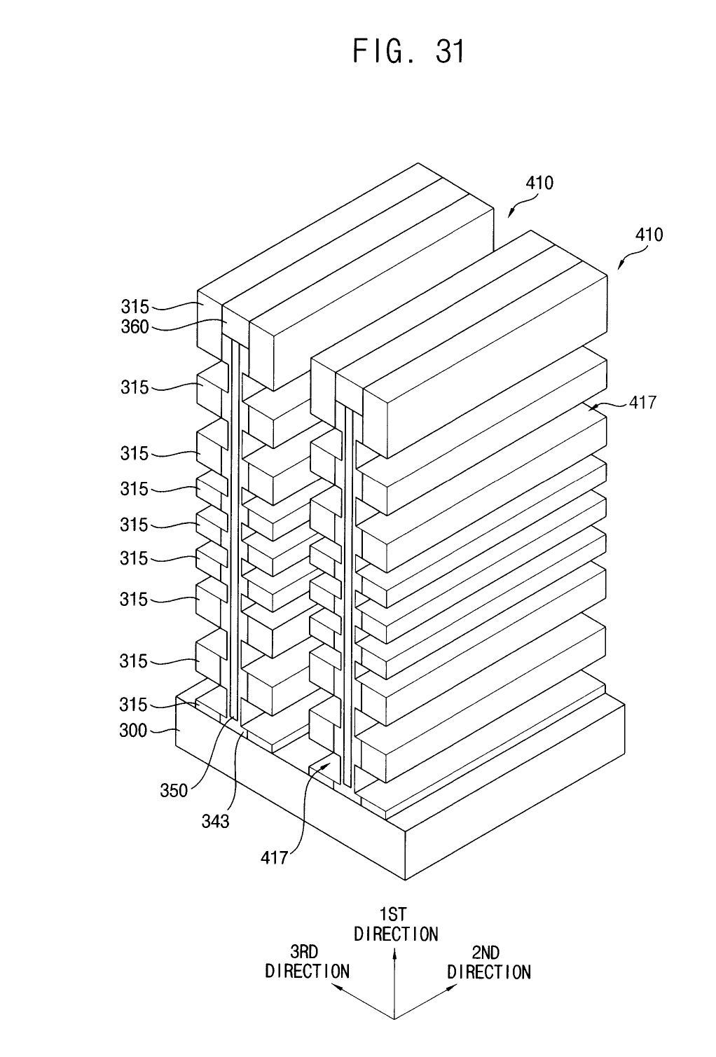

Referring to FIG. 31, a process substantially the same as or similar to that illustrated with reference to FIG. 14 may be performed.

That is, portions of the outer sidewall of the fourth channel layer pattern 342 exposed by the first gap 415 may be partially removed so that a second gap 417 larger than the first gap 415 may be formed.

According to example embodiments, the portions of the outer sidewall of the fourth channel layer pattern 342 may be removed by a wet etching process using, e.g., SC1. Alternatively, the portions of the outer sidewall of the fourth channel layer pattern 342 may be removed by a dry etching process using, e.g., Cl₂ or NF₃.

As the second gap 417 is formed, the fourth channel layer pattern 342 may be transformed to a fourth channel 343 having a thinner thickness at some portions. The GSL 456, the word line 452 and the SSL 454 (see FIG. 33) subsequently formed in the second gap 417 may have a low resistance. Additionally, the fourth channel 343 may have a relatively thin thickness at portions thereof adjacent to the GSL 456, the word line 452 and the 4SL 254 so that the GSL 456, the word line 452, and the SSL 454 have good swing characteristics.

Alternatively, only an upper portion of the sidewall of the fourth channel layer pattern 342 adjacent to SSL 454 exposed by the first gap 415 may be removed.

That is, referring to FIG. 32, an upper portion of the sidewall of the fourth channel layer pattern 342 exposed by the first gap 415 serving a space for subsequently forming the SSL 454 may be partially removed to form a sixth channel 344. Thus, the SSL 454 may have improved swing characteristics.

Hereinafter, only the vertical memory device having the fourth channel 343 is illustrated.

Referring to FIG. 33, processes substantially the same as or similar to those illustrated with reference to FIGS. 16-18 may be performed.

Thus, a tunnel insulation layer pattern 425, a charge trapping layer pattern 435 and a blocking layer pattern 445 may be sequentially formed on an inner wall of the second gap 417 and a sidewall of the first insulation layer pattern 315, and a GSL 456, a word line 452 and the SSL 454 may be formed at a remaining portion of the second gap 417.

An impurity region 305 serving as a CSL may be formed at an upper portion of the substrate 300 exposed by a third opening (not shown) extending in the second direction between a plurality of structures each of which may include the GSL 456, the word line 452, the SSL 454 and the first insulation layer pattern 315, and a second insulation layer pattern 460 filling the third opening and extending in the second direction may be formed. According to example embodiments, a plurality of second insulation layer patterns 460 may be formed in the third direction.

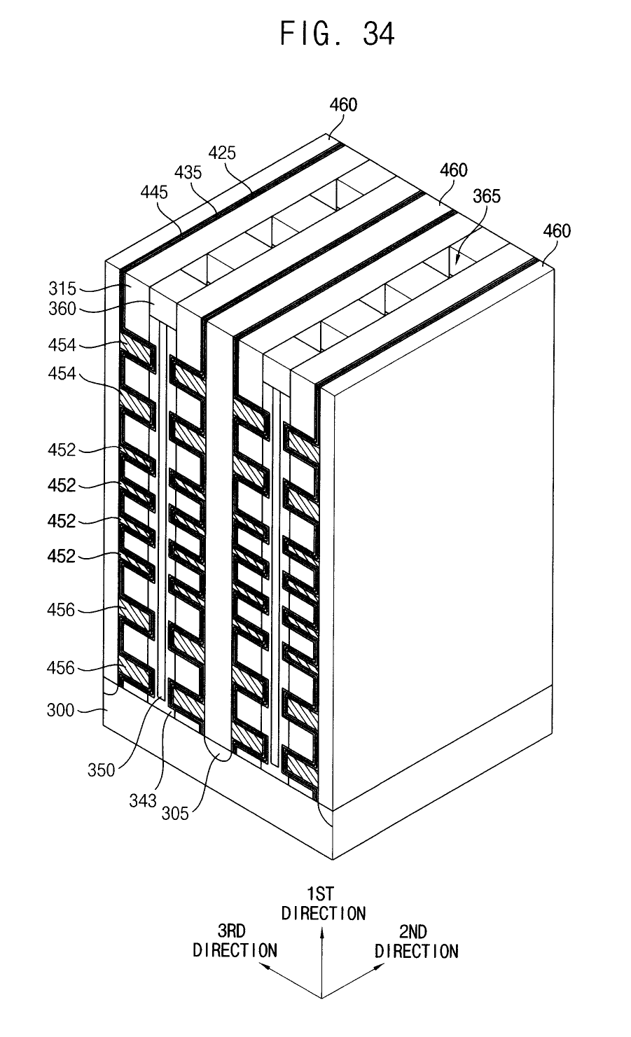

Referring to FIG. 34, the pad 360, the fourth channel 343, and the filling layer pattern 350 may be partially removed to form a fifth opening 365 exposing a top surface of the substrate 300 and extending in the first direction. According to example embodiments, a plurality of fifth openings 365 of an island shape may be formed in the second direction to define a fifth opening column, and a plurality of fifth opening columns may be formed in the third direction to define a fifth opening array.

Referring to FIG. 35, a third insulation layer pattern 465 may be formed in the fifth opening 365. A third insulation layer filling the fifth opening 365 may be formed on the substrate 300, the first and second insulation layer patterns 315 and 460, the pad 360, the blocking layer pattern 445, the charge trapping layer pattern 435 and the tunnel insulation layer pattern 425. The third insulation layer pattern may be planarized until a top surface of the first insulation layer pattern 315 is exposed to form the third insulation layer pattern 465. According to example embodiments, the third insulation layer may be formed to include an insulating material, for example, an oxide.

Referring to FIG. 36, a process substantially the same as or similar to that illustrated with reference to FIG. 1C may be performed.

A fourth insulation layer 470 may be formed on the first to third insulation layer patterns 315, 460 and 465, the pad 360, the blocking layer pattern 445, the charge trapping layer pattern 435 and the tunnel insulation layer pattern 425, and a fourth opening (not shown) may be formed to expose a top surface of the pad 360. According to example embodiments, a plurality of fourth openings may be formed in the second direction to define a fourth opening column, and a plurality of fourth opening columns may be formed in the third direction to define a fourth opening array.

A bit line contact 480 may be formed on the pad 360 to fill the fourth opening. The bit line contact 480 may be formed to include, for example, a metal, a metal nitride and/or doped polysilicon. According to example embodiments, a bit line contact column and a bit line contact array corresponding to the fourth opening column and the fourth opening array, respectively, may be formed.

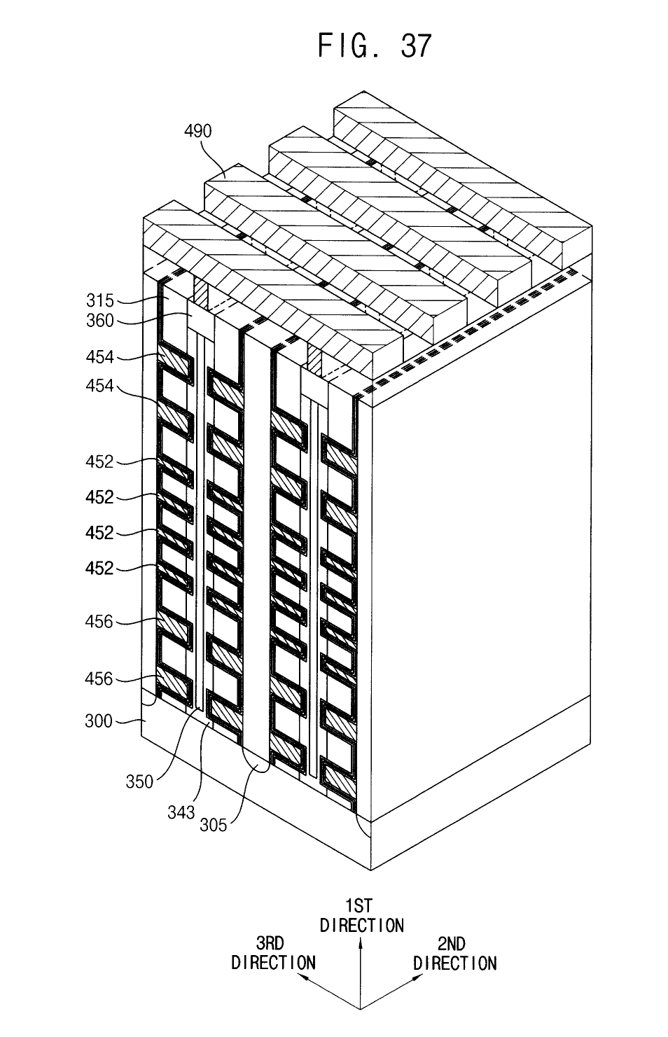

Referring to FIG. 37, a bit line 490 electrically connected to the bit line contact 480 may be formed to complete the vertical memory device. The bit line 490 may be formed to include, for example, a metal, a metal nitride and/or doped polysilicon. According to example embodiments, the bit line 490 may be formed to extend in the third direction.

The example embodiments above described may be employed in different types of vertical memory devices, such as DRAM (including DDR and SDRAM), NAND flash, NOR flash, RRAM, PRAM, and MRAM, or other memory devices etc. In addition, aspects of the disclosed embodiments may be used in systems such as cell phones, PDAs, tablet computers, laptops, desktop computers, microprocessor systems, digital signal processors, communication system processors, or other systems.

While example embodiments have been particularly shown and described, it will be understood by one of ordinary skill in the art that variations in form and detail may be made therein without departing from the spirit and scope of the claims.

What is claimed is:

1. A vertical memory device, comprising:
a first ground selection line (GSL), a plurality of first word lines and a first string selection line (SSL) spaced apart from each other on a substrate in a first direction perpendicular to a top surface of a substrate;
a plurality of first insulation layer patterns between the first GSL, the first word lines, and the first SSL; and
a first channel on the top surface of the substrate, the first channel extending in the first direction through the first GSL, the first word lines, the first SSL, and the first insulation layer patterns, the channel having a thickness thinner at a portion thereof adjacent to the first SSL than at portions thereof adjacent to the first insulation layer patterns.

2. The device of claim 1, wherein the channel has a recess at an outer lateral portion thereof, and the first SSL is adjacent to the recess.

3. The device of claim 1, wherein portions of the first channel adjacent to the first word lines and the first GSL have a thickness thinner than portions of the first channel adjacent to the first insulation layer patterns.

4. The device of claim 1, wherein the first channel includes an inner wall that is cup shaped and a filling layer pattern filling a space defined by the inner wall of the cup shaped channel.

5. The device of claim 1, wherein the first channel has a pillar shape.

6. The device of claim 1, wherein the first channel includes polysilicon.

7. The device of claim 1, further comprising:
a tunnel insulation layer pattern, a charge trapping layer pattern, and a blocking layer pattern sequentially stacked in a direction perpendicular to a sidewall of the first channel, wherein the tunnel insulation layer pattern, the charge trapping layer pattern, and the blocking layer pattern are disposed between the sidewall of the first channel and each of the first GSL, the first word lines, and the first SSL.

8. The device of claim 7, wherein the tunnel insulation layer pattern, the charge trapping layer pattern, and the blocking layer pattern are also sequentially stacked in the first direction between the first insulation layer patterns and each of the first GSL, the first word lines, and the first SSL.

9. The device of claim 1,
wherein the first channel is one of a plurality of channels formed in an array in a second direction and a third direction perpendicular to the second direction on the top surface of the substrate,
wherein each of the first GSL, the first word lines, and the first SSL has a bar shape extending in the second direction, and
wherein additional channels, GSLs, word lines, and SSLs are spaced apart from the first channel, the first GSL, the first word lines, and the first SSL, respectively, in the third direction.

10. The device of claim 9, further comprising a bit line electrically connected to a set of channels extending in the third direction.

11. A vertical memory device, comprising:
a plurality of conductive lines spaced apart from each other on a substrate in a vertical direction perpendicular to a top surface of a substrate;
a plurality of insulation layer patterns, each disposed between two consecutive conductive lines; and
a channel disposed on the top surface of the substrate and extending in the vertical direction through the plurality of lines and the plurality of insulation layer patterns,
wherein the channel includes at least a first laterally recessed portion at a first vertical level and at least a first laterally non-recessed portion at a second vertical level.

12. The vertical memory device of claim 11, wherein:
at least one of the conductive lines is disposed at the same vertical level as the first laterally recessed portion; and
at least one of the insulation layer patterns is disposed at the same vertical level as the first laterally non-recessed portion.

13. The vertical memory device of claim 12, wherein:
at least one of the conductive lines is one of a string selection line (SSL), a ground selection line (GSL), and one of a plurality of word lines disposed at the same vertical level, respectively, as the first laterally recessed portion.

14. A method of manufacturing a vertical memory device, the method comprising:
forming a plurality of sacrificial layers and first insulation layers alternately and repeatedly on a substrate in a first direction;
forming a first opening through the plurality of sacrificial layers and first insulation layers to expose a top surface of the substrate;
forming a channel layer in the first opening and on the substrate;
forming a second opening through the plurality of sacrificial layers and first insulation layers to expose a top surface of the substrate, wherein the second opening is located adjacent to the first opening in a second direction perpendicular to the first direction;
removing the sacrificial layers to form a plurality of gaps between the plurality of first insulation layers to expose outer sidewalls of the channel layer by the plurality of gaps;
partially removing the exposed outer sidewalls of the channel layer to form recesses in the channel layer; and
forming a plurality of conductive layers to fill the plurality of gaps.

15. The method of claim 14, further comprising:
partially removing the exposed outer sidewalls of the channel layer so that a thickness of the channel layer at the same vertical level as at least one of the conductive layers is smaller than a thickness of the channel layer at the same vertical level as at least one of the first insulation layers.

16. The method of claim 14, wherein forming a channel layer includes:
forming a polysilicon layer on a sidewall of the first opening and on the substrate.

17. The method of claim 16, further comprising performing a heat treatment to enlarge grain size of the polysilicon layer.

18. The method of claim 14, further comprising:
forming a tunnel insulation layer, a charge trapping layer, and a blocking layer on the inner wall of the plurality of gaps sequentially after partially removing the exposed outer sidewall of the channel layer.

19. The method of claim 14, further comprising forming a second insulation layer in the first opening.

20. The method of claim 14, further comprising:
forming a plurality of third openings extending in the first direction and through the channel layer to expose a top surface of the substrate, wherein the plurality of third openings are formed along a third direction perpendicular to the second direction.
